(19) United States
(12) Patent Application Publication
(10) Pub. No.: US 2026/0271296 A1
(43) Pub. Date: Sep. 10, 2026

(54) MEMORY DEVICE

(71) Applicant: Kioxia Corporation, Tokyo (JP)

(72) Inventors: Yuta TSUCHIYA, Yokkaichi Mie (JP); Kenji AOYAMA, Yokkaichi Mie (JP); Kota HORIKAWA, Yokkaichi Mie (JP); Shunsuke OKADA, Suzuka Mie (JP); Hiroshi KUBOTA, Yokkaichi Mie (JP)

(73) Assignee: Kioxia Corporation, Tokyo (JP)

(21) Appl. No.: 19/303,474

(22) Filed: Aug. 19, 2025

(30) Foreign Application Priority Data
Mar. 6, 2025 (JP) 2025-035877

(51) Int. Cl. H10B 43/35; H10B 43/10; H10B 43/27

(52) U.S. Cl. CPC H10B 43/35; H10B 43/10; H10B 43/27

(57) ABSTRACT

According to one embodiment, a memory device includes: a semiconductor layer, a first wiring layer, and second wiring layers apart from each other in a first direction; memory pillars including portions respectively intersecting with the second wiring layers each functioning as a memory cell; and a member extending in a first plane and dividing the first and second wiring layers in a third direction. The member includes a filling material extending in the first plane and having both ends in the first direction located on a side of the second wiring layers with respect to a semiconductor layer side surface of the first wiring layer, and an insulating material provided between the filling material and each of the semiconductor layer and the first and second wiring layers, and having a thermal conductivity lower than that of the filling material.

### CROSS-REFERENCE TO RELATED APPLICATION

This application is based upon and claims the benefit of priority from Japanese Patent Application No. 2025-035877, filed Mar. 6, 2025, the entire contents of which are incorporated herein by reference.

### FIELD

Embodiments described herein relate generally to a memory device.

### BACKGROUND

A NAND flash memory is known as a memory device capable of storing data in a non-volatile manner. In a memory device such as a NAND flash memory, a three-dimensional memory structure is adopted for high integration and large capacity.

### BRIEF DESCRIPTION OF THE DRAWINGS

FIG. 1 is a block diagram illustrating an example of a configuration of a memory system including a memory device according to a first embodiment.

FIG. 2 is a circuit diagram illustrating an example of a circuit configuration of a memory cell array included in the memory device according to the first embodiment.

FIG. 3 is a plan view illustrating an example of a planar layout of the memory cell array included in the memory device according to the first embodiment.

FIG. 4 is a plan view illustrating an example of a planar layout in a region IV of FIG. 3 in the memory cell array included in the memory device according to the first embodiment.

FIG. 5 is a cross-sectional view taken along a line V-V of FIG. 4, illustrating an example of a cross-sectional structure of the memory cell array included in the memory device according to the first embodiment.

FIG. 6 is a cross-sectional view taken along a line VI-VI of FIG. 5, illustrating an example of a cross-sectional structure of a memory pillar included in the memory device according to the first embodiment.

FIG. 7 is a perspective view illustrating an outline of a bonding structure of the memory device according to the first embodiment.

FIG. 8 is a cross-sectional view illustrating an example of a cross-sectional structure of bonding pads included in the memory device according to the first embodiment.

FIG. 9 is a cross-sectional view illustrating an example of a cross-sectional structure of the memory device according to the first embodiment.

FIG. 10 is a cross-sectional view illustrating an example of a cross-sectional structure in a process of manufacturing the memory device according to the first embodiment.

FIG. 11 is a cross-sectional view illustrating an example of a cross-sectional structure in the process of manufacturing the memory device according to the first embodiment.

FIG. 12 is a cross-sectional view illustrating an example of a cross-sectional structure in the process of manufacturing the memory device according to the first embodiment.

FIG. 13 is a cross-sectional view illustrating an example of a cross-sectional structure in the process of manufacturing the memory device according to the first embodiment.

FIG. 14 is a cross-sectional view illustrating an example of a cross-sectional structure in the process of manufacturing the memory device according to the first embodiment.

FIG. 15 is a cross-sectional view illustrating an example of a cross-sectional structure in the process of manufacturing the memory device according to the first embodiment.

FIG. 16 is a cross-sectional view illustrating an example of a cross-sectional structure in the process of manufacturing the memory device according to the first embodiment.

FIG. 17 is a cross-sectional view illustrating an example of a cross-sectional structure in the process of manufacturing the memory device according to the first embodiment.

FIG. 18 is a cross-sectional view illustrating an example of a cross-sectional structure in the process of manufacturing the memory device according to the first embodiment.

FIG. 19 is a cross-sectional view illustrating an example of a cross-sectional structure of a memory cell array included in a memory device according to a modification of the first embodiment.

FIG. 20 is a cross-sectional view illustrating an example of a cross-sectional structure of a memory cell array included in a memory device according to a second embodiment.

FIG. 21 is a cross-sectional view illustrating an example of a cross-sectional structure in a process of manufacturing the memory device according to the second embodiment.

FIG. 22 is a cross-sectional view illustrating an example of a cross-sectional structure in the process of manufacturing the memory device according to the second embodiment.

FIG. 23 is a cross-sectional view illustrating an example of a cross-sectional structure in the process of manufacturing the memory device according to the second embodiment.

FIG. 24 is a cross-sectional view illustrating an example of a cross-sectional structure in the process of manufacturing the memory device according to the second embodiment.

FIG. 25 is a cross-sectional view illustrating an example of a cross-sectional structure of a memory cell array included in a memory device according to a first modification of the second embodiment.

FIG. 26 is a cross-sectional view illustrating an example of a cross-sectional structure of a memory cell array included in a memory device according to a second modification of the second embodiment.

FIG. 27 is a cross-sectional view illustrating an example of a cross-sectional structure of a memory cell array included in a memory device according to a third embodiment.

FIG. 28 is a cross-sectional view illustrating an example of a cross-sectional structure in a process of manufacturing the memory device according to the third embodiment.

FIG. 29 is a cross-sectional view illustrating an example of a cross-sectional structure in the process of manufacturing the memory device according to the third embodiment.

FIG. 30 is a cross-sectional view illustrating an example of a cross-sectional structure in the process of manufacturing the memory device according to the third embodiment.

FIG. 31 is a cross-sectional view illustrating an example of a cross-sectional structure in the process of manufacturing the memory device according to the third embodiment.

FIG. 32 is a cross-sectional view illustrating an example of a cross-sectional structure in the process of manufacturing the memory device according to the third embodiment.

FIG. 33 is a cross-sectional view illustrating an example of a cross-sectional structure of a memory cell array included in a memory device according to a first modification of the third embodiment.

FIG. 34 is a cross-sectional view illustrating an example of a cross-sectional structure of a memory cell array included in a memory device according to a second modification of the third embodiment.

FIG. 35 is a cross-sectional view illustrating an example of a cross-sectional structure of a memory cell array included in a memory device according to a third modification of the third embodiment.

FIG. 36 is a cross-sectional view illustrating an example of a cross-sectional structure of a memory cell array included in a memory device according to a fourth modification of the third embodiment.

FIG. 37 is a cross-sectional view illustrating an example of a cross-sectional structure of a memory cell array included in a memory device according to a fourth embodiment.

FIG. 38 is a cross-sectional view illustrating an example of a cross-sectional structure in a process of manufacturing the memory device according to the fourth embodiment.

FIG. 39 is a cross-sectional view illustrating an example of a cross-sectional structure in the process of manufacturing the memory device according to the fourth embodiment.

FIG. 40 is a cross-sectional view illustrating an example of a cross-sectional structure of a memory cell array included in a memory device according to a modification of the fourth embodiment.

### DETAILED DESCRIPTION

In general, according to one embodiment, a memory device includes: a semiconductor layer; a first wiring layer arranged apart from the semiconductor layer in a first direction without interposing another wiring layer; a plurality of second wiring layers located on a side opposite to a side of the semiconductor layer with respect to the first wiring layer and arranged apart from each other in the first direction; a plurality of memory pillars each extending in the first direction, being in contact with the semiconductor layer, and including portions respectively intersecting with the second wiring layers each functioning as a memory cell; and a member extending in a first plane including the first direction and a second direction intersecting with the first direction and dividing the first wiring layer and the second wiring layers in a third direction intersecting with each of the first direction and the second direction. The member includes a filling material extending in the first plane and having both ends in the first direction that are located on a side of the second wiring layers with respect to a semiconductor layer side surface of the first wiring layer, and an insulating material provided between the filling material and each of the semiconductor layer, the first wiring layer, and the second wiring layers, and having a thermal conductivity that is lower than a thermal conductivity of the filling material.

Hereinafter, embodiments will be described with reference to the drawings. Dimensions and ratios of the drawings are not necessarily the same as actual ones.

In the following description, components having substantially the same functions and configurations are denoted by the same reference numerals. In a case where the components having similar configurations are particularly distinguished from each other, different characters or numbers may be added to the end of the same reference numeral.

### 1. First Embodiment

### 1.1 Configuration

### 1.1.1 Configuration of Memory System

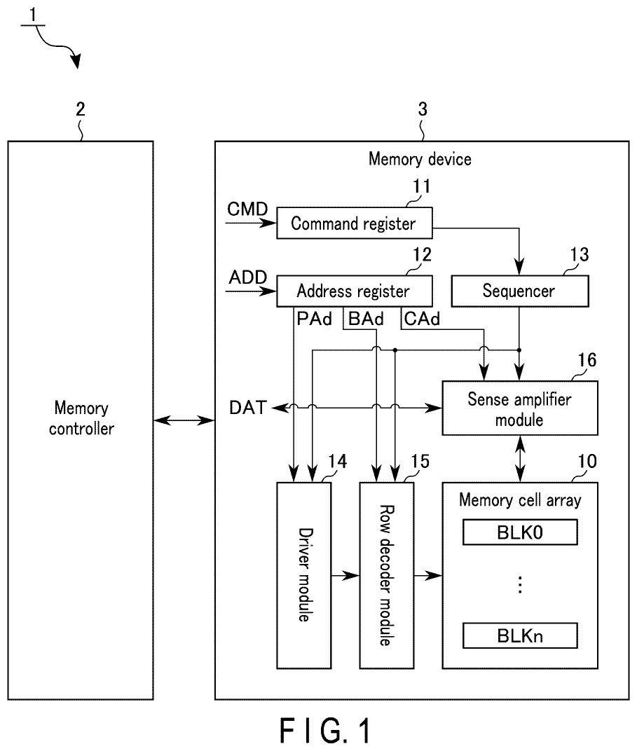

FIG. 1 is a block diagram illustrating an example of a configuration of a memory system including a memory device according to a first embodiment. A memory system 1 is a storage device configured to be connected to an external host (not illustrated). The memory system 1 is, for example, a memory card such as an SD™ card, a universal flash storage (UFS), or a solid state drive (SSD). The memory system 1 includes a memory controller 2 and a memory device 3.

The memory controller 2 includes, for example, an integrated circuit such as a system-on-a-chip (SoC). The memory controller 2 controls the memory device 3 based on a request from the host. Specifically, for example, the memory controller 2 writes data, which is requested by the host to write, to the memory device 3. In addition, the memory controller 2 reads data, which is requested by the host to read, from the memory device 3 and transmits the data to the host.

The memory device 3 is a non-volatile memory. The memory device 3 is, for example, a NAND flash memory. The memory device 3 stores data in a non-volatile manner.

Communication between the memory controller 2 and the memory device 3 conforms to, for example, a single data rate (SDR) interface, a toggle double data rate (DDR) interface, or an open NAND flash interface (ONFI).

### 1.1.2 Configuration of Memory Device

With reference to the block diagram illustrated in FIG. 1, an internal configuration of the memory device according to the first embodiment will be described. The memory device 3 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (n is an integer equal to or greater than one). The number of blocks BLK included in the memory cell array 10 may be one. The block BLK is a set of a plurality of memory cells. The block BLK is used, for example, as a data erasing unit. A plurality of bit lines and a plurality of word lines are provided in the memory cell array 10. Each memory cell is associated with a bit line and a word line, for example. A detailed configuration of the memory cell array 10 will be described later.

The command register 11 stores a command CMD received by the memory device 3 from the memory controller 2. The command CMD includes, for example, an order for causing the sequencer 13 to execute a read operation, a write operation, an erase operation, and the like.

The address register 12 stores address information ADD received by the memory device 3 from the memory controller 2. The address information ADD includes, for example, a block address BAd, a page address PAd, and a column address CAd. For example, the block address BAd, the page address PAd, and the column address CAd are used to select a block BLK, a word line, and a bit line, respectively.

The sequencer 13 controls the entire operation of the memory device 3. For example, the sequencer 13 controls the driver module 14, the row decoder module 15, the sense amplifier module 16, and the like based on the command CMD stored in the command register 11 to execute the read operation, write operation, erase operation, and the like.

The driver module 14 generates a voltage used in the read operation, write operation, erase operation, and the like. Then, the driver module 14 applies the generated voltage to a signal line corresponding to a selected word line based on, for example, the page address PAd stored in the address register 12.

The row decoder module 15 selects a block BLK in the corresponding memory cell array 10 based on the block address BAd stored in the address register 12. Then, the row decoder module 15 transfers, for example, the voltage applied to the signal line corresponding to the selected word line to the selected word line in the selected block BLK.

In the write operation, the sense amplifier module 16 applies a desired voltage to each bit line according to write data DAT received from the memory controller 2. In addition, in the read operation, the sense amplifier module 16 determines the data stored in the memory cell based on the voltage of the bit line, and transfers the determination result to the memory controller 2 as read data DAT.

### 1.1.3 Memory Cell Array

Next, a configuration of the memory cell array included in the memory device according to the first embodiment will be described.

### 1.1.3.1 Circuit Configuration

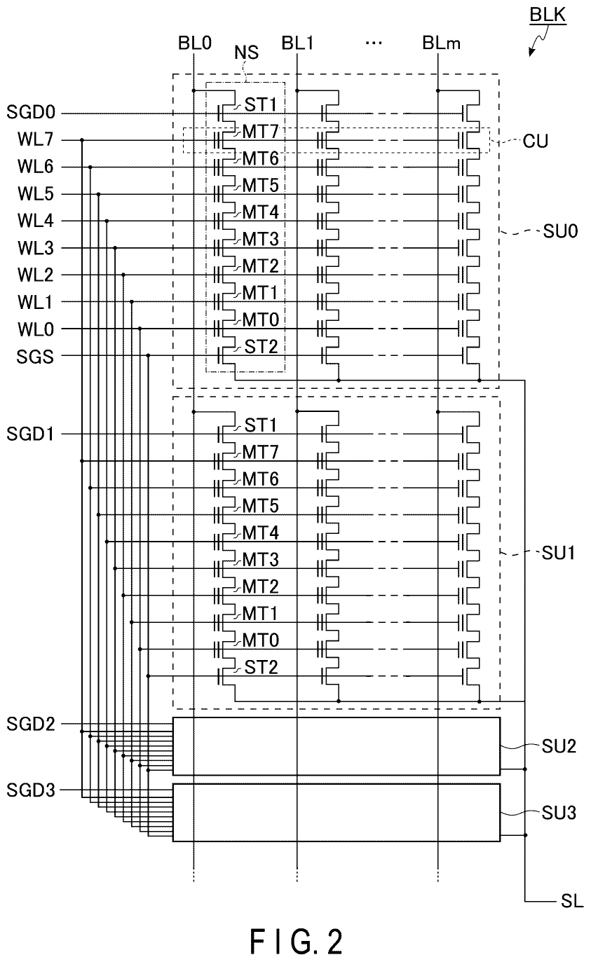

FIG. 2 is a circuit diagram illustrating an example of a circuit configuration of the memory cell array included in the memory device according to the first embodiment. FIG. 2 illustrates a block BLK among the blocks BLK included in the memory cell array 10. As illustrated in FIG. 2, the block BLK includes, for example, four string units SU0 to SU3.

Each string unit SU includes a plurality of NAND strings NS respectively associated with bit lines BL0 to BLm (m is an integer equal to or greater than one). The number of the bit lines BL may be one. Each NAND string NS includes, for example, memory cell transistors MT0 to MT7 and select transistors ST1 and ST2. Each memory cell transistor MT includes a control gate and a charge storage film, and stores data in a non-volatile manner. Each of the select transistors ST1 and ST2 is used to select the string unit SU during various operations.

In each NAND string NS, the memory cell transistors MT0 to MT7 are connected in series. A drain of the select transistor ST1 is connected to an associated bit line BL. A source of the select transistor ST1 is connected to one end of the memory cell transistors MT0 to MT7 connected in series. A drain of the select transistor ST2 is connected to the other end of the memory cell transistors MT0 to MT7 connected in series. A source of the select transistor ST2 is connected to the source line SL.

In a same block BLK, the control gates of the memory cell transistors MT0 to MT7 are connected to the word lines WL0 to WL7, respectively. The gates of the select transistor ST1 in the string units SU0 to SU3 are connected to select gate lines SGD0 to SGD3, respectively. The gates of the select transistors ST2 are connected to the select gate line SGS.

Different column addresses are allocated to the bit lines BL0 to BLm. Each bit line BL is shared by the NAND strings NS to which the same column address is allocated among the blocks BLK. Each of the word lines WL0 to WL7 is provided for each block BLK. The source line SL is shared among the blocks BLK, for example.

A set of the memory cell transistors MT connected to the common word line WL in a string unit SU is referred to as, for example, a cell unit CU. For example, the storage capacity of the cell unit CU including the memory cell transistors MT each storing one-bit data is defined as “one-page data”. The cell unit CU may have a storage capacity of two-page data or more according to the number of bits of data stored in the memory cell transistor MT.

Note that the circuit configuration of the memory cell array 10 included in the memory device 3 according to the first embodiment is not limited to the configuration described above. For example, the number of string units SU included in each block BLK can be designed to an any number. The number of the memory cell transistors MT and the select transistors ST1 and ST2 included in each NAND string NS can be designed to any number.

### 1.1.3.2 Planar Layout

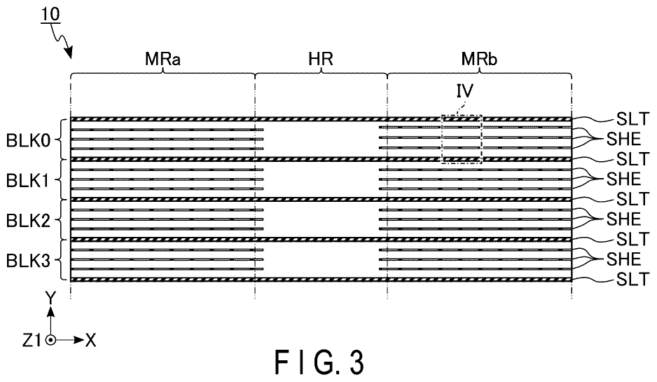

FIG. 3 is a plan view illustrating an example of a planar layout of the memory cell array included in the memory device according to the first embodiment. FIG. 3 illustrates four blocks BLK0 to BLK3 of the blocks BLK included in the memory cell array 10.

The memory cell array 10 includes a stacked wiring structure. The stacked wiring structure is a structure in which wiring layers (word lines WL0 to WL7 and select gate lines SGD and SGS) are stacked.

Hereinafter, a plane substantially parallel to the stacking plane of the wiring layer is referred to as an XY plane. Directions orthogonal to each other on the XY plane are defined as an X direction and a Y direction. A direction substantially perpendicular to the XY plane and extending from the select gate line SGS to the select gate line SGD is defined as a Z1 direction. A direction substantially perpendicular to the XY plane and extending from the select gate line SGD to the select gate line SGS is defined as a Z2 direction. In a case where the Z1 direction and the Z2 direction are not distinguished, the direction is referred to as a Z direction.

As illustrated in FIG. 3, the stacked wiring structure includes memory regions MRa and MRb arranged in the X direction and a hookup region HR. The memory regions MRa and MRb are regions in which the memory cell transistor MT is provided. The hookup region HR is a region provided with contacts that electrically connect each wiring layer and the row decoder module 15. The hookup region HR is located, for example, between the memory region MRa and the memory region MRb in the X direction.

Each of the blocks BLK includes a portion extending in the X direction so as to cross the memory region MRa, the hookup region HR, and the memory region MRb in the stacked wiring structure. The blocks BLK are arranged in the Y direction. The memory cell array 10 includes, for example, a plurality of members SLT and a plurality of members SHE.

Although not illustrated in FIG. 3, for example, each member SLT has a structure in which a plate-shaped filling material LI is embedded in a plate-shaped insulating material SP. Each member SLT extends in the X direction so as to cross the memory region MRa, the hookup region HR, and the memory region MRb. The members SLT are arranged in the Y direction. Each member SLT divides the adjacent wiring layers via the member SLT. In the memory cell array 10, each of the regions divided by the member SLT corresponds to one block BLK.

Each member SHE is, for example, a plate-shaped insulator. The members SHE include a plurality of members SHE arranged in the Y direction in the memory region MRa and a plurality of members SHE arranged in the Y direction in the memory region MRb. Each member SHE disposed in the memory region MRa extends in the X direction so as to cross the memory region MRa. Each member SHE disposed in the memory region MRb extends in the X direction so as to cross the memory region MRb.

In the example of FIG. 3, in each of the memory regions MRa and MRb, three members SHE are arranged between two members SLT adjacent in the Y direction. Each member SHE has, for example, a structure in which an insulator is embedded. Each member SHE divides the select gate line SGD in the wiring layers adjacent to each other with the member SHE interposed therebetween. In the memory cell array 10, each of regions divided by a pair of adjacent members SLT and SHE or a pair of adjacent two members SHE corresponds to one string unit SU.

The planar layout of the memory cell array 10 may be a different layout. For example, the number of members SHE disposed between two adjacent members SLT can be designed to be any number. The number of string units SU included in each block BLK can be changed based on the number of members SHE arranged between two adjacent members SLT.

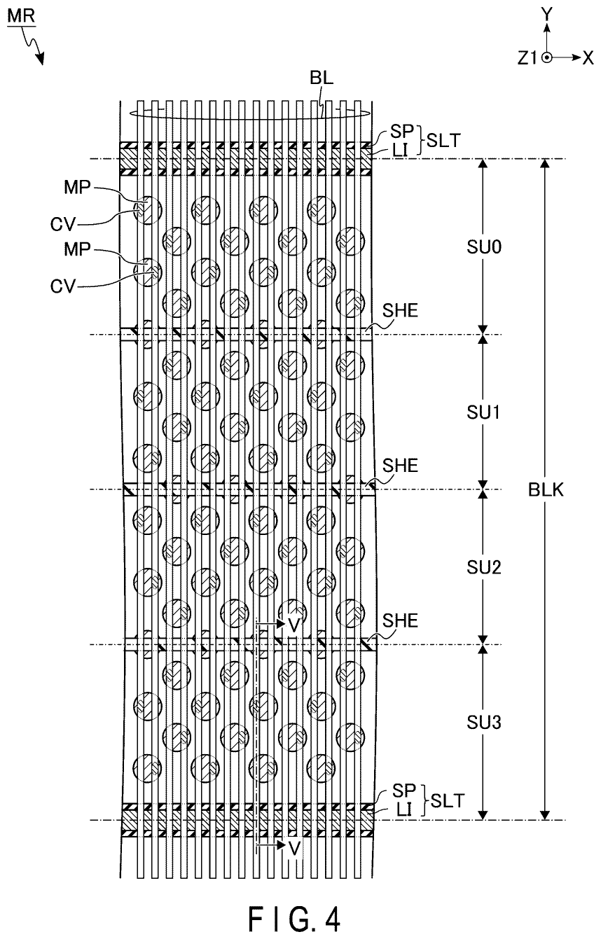

FIG. 4 is a plan view illustrating an example of a planar layout in the region IV of FIG. 3 in the memory cell array included in the memory device according to the first embodiment. FIG. 4 illustrates a part of the memory region MRb in the block BLK0. Note that, although not illustrated in FIG. 4, the memory region MRa has the same configuration as the memory region MRb.

As illustrated in FIG. 4, the memory cell array 10 includes a plurality of memory pillars MP, a plurality of contacts CV, and a plurality of bit lines BL in the memory region MR.

Each memory pillar MP functions as a NAND string NS. The memory pillars MP are arranged in 19 rows in a staggered manner, for example, in a region between two adjacent members SLT. For example, one member SHE is arranged to overlap each of the memory pillars MP of the fifth column, the memory pillars MP of the tenth column, and the memory pillars MP of the fifteenth column in a case of counting from the upper side in the drawing.

The bit lines BL extend in the Y direction and are arranged in the X direction. Each bit line BL is arranged so as to overlap at least one memory pillar MP in each string unit SU. In the example of FIG. 4, two bit lines BL are arranged to overlap a memory pillar MP. The memory pillar MP is electrically connected to one bit line BL among the bit lines BL arranged in an overlapping manner via the contact CV. On the other hand, the contact CV between the memory pillar MP arranged to overlap with the member SHE (that is, the memory pillar MP in contact with two different select gate lines SGD) and the bit line BL may be omitted.

Note that the planar layout in the memory region MR may be a different layout. For example, the number and arrangement of the memory pillars MP and the members SHE arranged between two adjacent members SLT may be appropriately changed. The number of bit lines BL overlapping each memory pillar MP can be designed to an any number.

### 1.1.3.3 Cross-Sectional Structure

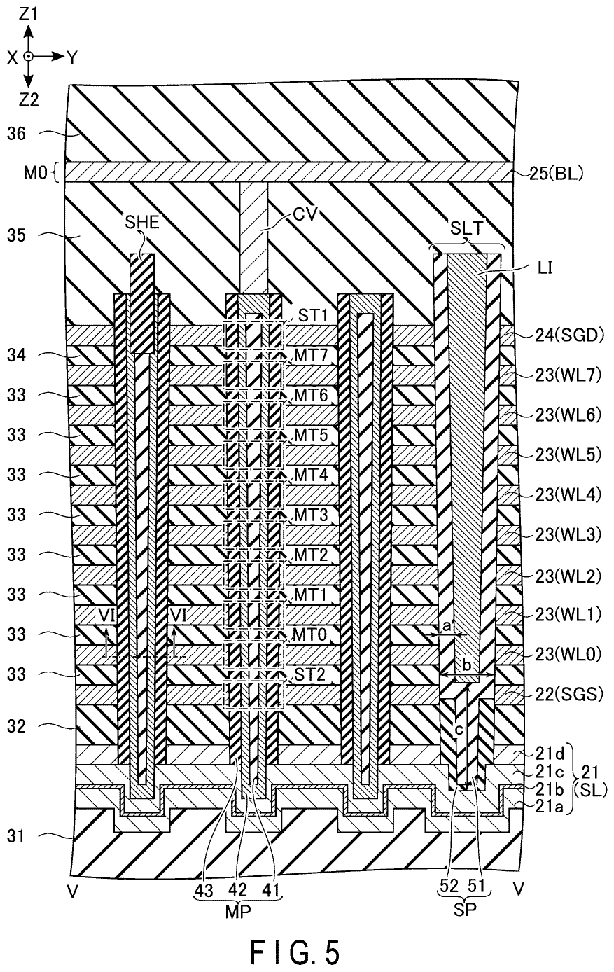

FIG. 5 is a cross-sectional view taken along the line V-V of FIG. 4, illustrating an example of a cross-sectional structure of the memory cell array included in the memory device according to the first embodiment. FIG. 5 illustrates a YZ cross-sectional structure of the memory region MR.

As illustrated in FIG. 5, the memory cell array 10 includes, for example, wiring layers 21, 22, 23, and 24, a conductive layer 25, and insulating layers 31, 32, 33, 34, 35, and 36. The insulating layers 31, 32, 33, 34, 35, and 36 include, for example, silicon oxide. In FIG. 5, the Z1 direction corresponds to the upper direction in the drawing.

The wiring layer 21 is provided on the insulating layer 31. The wiring layer 21 is formed in, for example, a plate shape extending in the XY plane. The wiring layer 21 is used as the source line SL. The wiring layer 21 includes conductive layers 21a and 21b and semiconductor layers 21c and 21d. The surfaces of the conductive layers 21a and 21b and the semiconductor layer 21c on the Z2 direction side are formed to have unevenness so as to protrude in the Z2 direction in regions overlapping the memory pillars MP and the member SLT as viewed in the Z direction.

The conductive layer 21a is provided on the surface of the insulating layer 31 on the Z1 direction side. The conductive layer 21a has a shape in which portions overlapping the memory pillar MP and the member SLT as viewed in the Z direction are Z2 direction side with respect to other portion. The conductive layer 21a contains, for example, tungsten, and has a function of lowering a resistance value of the source line SL.

The conductive layer 21b is provided on a surface of the conductive layer 21a on the Z1 direction side. The conductive layer 21b has a shape in which portions overlapping the memory pillar MP and the member SLT as viewed in the Z direction are Z2 direction side with respect to other portion. The conductive layer 21b contains, for example, titanium nitride and is used as a barrier metal.

The semiconductor layer 21c is provided on a surface of the conductive layer 21b on the Z1 direction side. The semiconductor layer 21c has a shape in which portions overlapping the memory pillar MP and the member SLT as viewed in the Z direction are Z2 direction side with respect to other portion. The semiconductor layer 21c covers an end on the Z2 direction side of a semiconductor film 42 of the memory pillar MP described later and an end on the Z2 direction side of an insulating film 52 of the member SLT described later. The semiconductor layer 21c includes, for example, polysilicon.

The semiconductor layer 21d is provided on a surface of the semiconductor layer 21c on the Z1 direction side. The semiconductor layer 21d is formed in, for example, a plate shape extending in the XY plane. The semiconductor layer 21d contains, for example, polysilicon.

On a surface of the semiconductor layer 21d on the Z1 direction side, the insulating layer 32 is provided. On a surface of the insulating layer 32 on the Z1 direction side, the wiring layer 22 is provided. The wiring layer 22 is formed in, for example, a plate shape extending in the XY plane. The wiring layer 22 contains, for example, tungsten or molybdenum, and is used as the select gate line SGS.

The insulating layers 33 and the wiring layers 23 are alternately provided on a surface of the wiring layer 22 on the Z1 direction side. The wiring layers 23 are formed in, for example, a plate shape extending in the XY plane. The wiring layers 23 contain, for example, tungsten or molybdenum, and are used as the word lines WL0 to WL7, respectively, in order from the wiring layer 21 side.

The insulating layer 34 is provided on a surface of the uppermost wiring layer 23 on the Z1 direction side. The wiring layer 24 is provided on a surface of the insulating layer 34 on the Z1 direction side. The wiring layer 24 is formed in, for example, a plate shape extending in the XY plane. The wiring layer 24 contains, for example, tungsten or molybdenum, and is used as the select gate line SGD. The insulating layer 35 is provided on a surface of the wiring layer 24 on the Z1 direction side.

Each of the memory pillars MP extends in the Z direction and penetrates the wiring layers 22 to 24 and the insulating layers 32 to 34. Each of the memory pillars MP includes, for example, a core film 41, the semiconductor film 42, and a stacked film 43. The core film 41 is an insulator extending in the Z direction. The semiconductor film 42 covers the core film 41. An end portion of the semiconductor film 42 on the Z2 direction side is in contact with the semiconductor layer 21c. The stacked film 43 covers a portion of a side surface of the semiconductor film 42 excluding the end portion on the Z2 direction side. An end surface of the stacked film 43 on the Z2 direction side is aligned with, for example, a surface of the semiconductor layer 21d on the Z2 direction side.

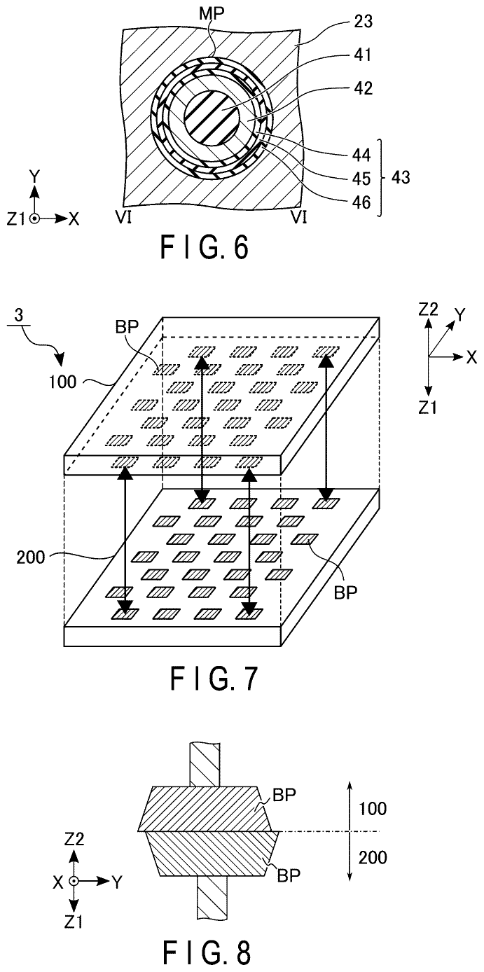

FIG. 6 is a cross-sectional view taken along the line VI-VI of FIG. 5, illustrating an example of a cross-sectional structure of the memory pillar included in the memory device according to the first embodiment. FIG. 6 illustrates a cross section including the memory pillar MP and the wiring layer 23 and being parallel to the XY plane. As illustrated in FIG. 6, the stacked film 43 includes, for example, a tunnel insulating film 44, a charge storage film 45, and a block insulating film 46.

The core film 41 is provided, for example, in a central portion of the memory pillar MP. The semiconductor film 42 surrounds the core film 41 as viewed in the Z direction. The tunnel insulating film 44 surrounds the semiconductor film 42 as viewed in the Z direction. The charge storage film 45 surrounds the tunnel insulating film 44 as viewed in the Z direction. The block insulating film 46 surrounds the charge storage film 45 as viewed in the Z direction. The wiring layer 23 surrounds the block insulating film 46 as viewed in the Z direction. The semiconductor film 42 is used as a channel (current path) of the memory cell transistors MT0 to MT7 and the select transistors ST1 and ST2. Each of the tunnel insulating film 44 and the block insulating film 46 contains, for example, silicon oxide. The charge storage film 45 includes, for example, silicon nitride.

With the above configuration, each of the memory pillars MP functions as a NAND string NS. In other words, a portion where the memory pillar MP intersects the wiring layer 22 functions as the select transistor ST2. A portion where the memory pillar MP intersects the wiring layer 23 functions as the memory cell transistor MT. A portion where the memory pillar MP intersects the wiring layer 24 functions as the select transistor ST1.

The contact CV is provided on the surface of the semiconductor film 42 on the Z1 direction side in the memory pillar MP. On the surface of the contact CV on the Z1 direction side, the conductive layer 25 is provided. The conductive layer 25 is formed in, for example, a line shape extending in the Y direction. The conductive layer 25 contains, for example, copper and is used as the bit line BL. On a surface of the conductive layer 25 on the Z1 direction side, the insulating layer 36 is provided. The layer on which the conductive layer 25 is provided is also referred to as a layer M0.

The filling material LI is a plate-shaped member extending in the XZ plane. The filling material LI has higher thermal conductivity and Young's modulus than the insulating material SP. The filling material LI contains, for example, tungsten or polysilicon. The filling material LI intersects the wiring layers 23 and 24 and the insulating layers 33 to 35. The end surface on the Z2 direction side of the filling material LI is located on the Z1 direction side with respect to the surface on the Z2 direction side of the wiring layer 22.

The insulating material SP includes insulating films 51 and 52. The insulating film 51 is an insulator that covers the end surface on the Z2 direction side and the side surface of the filling material LI. The insulating film 51 has a portion (bottom portion) extending in the Z direction on the Z2 direction side with respect to the filling material LI. The bottom portion of the insulating film 51 reaches the semiconductor layer 21c, for example. The insulating film 52 is provided so as to cover the bottom portion of the insulating film 51 in the Z2 direction. The insulating films 51 and 52 contain, for example, silicon oxide. In a case where the filling material LI has conductivity, the insulating films 51 and 52 electrically insulate the filling material LI from each of the wiring layers 22 to 24.

In the member SLT including the filling material LI and the insulating material SP as described above, the width “b” of the member SLT in the Y direction is larger than twice the film thickness “a” of the portion covering the side surface of the filling material LI in the insulating film 51. The distance “c” from the end surface on the Z2 direction side of the insulating material SP to the end surface on the Z2 direction side of the filling material LI is larger than the film thickness “a” of the insulating film 51.

### 1.1.4 Structure of Memory Device

Next, a structure of the memory device according to the first embodiment will be described.

### 1.1.4.1 Bonding Structure

FIG. 7 is a perspective view illustrating an outline of a bonding structure of the memory device according to the first embodiment. As illustrated in FIG. 7, the memory device 3 includes a memory chip 100 and a circuit chip 200. The memory chip 100 includes a structure corresponding to the memory cell array 10. The circuit chip 200 includes, for example, a structure corresponding to the command register 11, the address register 12, the sequencer 13, the driver module 14, the row decoder module 15, and the sense amplifier module 16.

In addition, each of the memory chip 100 and the circuit chip 200 includes a plurality of bonding pads BP. The memory device 3 is formed by bonding the memory chip 100 and the circuit chip 200 via the bonding pads BP.

### 1.1.4.2 Bonding Pad

FIG. 8 is a cross-sectional view illustrating an example of a cross-sectional structure of the bonding pads included in the memory device according to the first embodiment. In the example of FIG. 8, the bonding pad BP of each of the memory chip 100 and the circuit chip 200 on bonding plane and the contacts connected to the bonding pads BP are illustrated.

As illustrated in FIG. 8, in the bonding step, the bonding pad BP of the memory chip 100 is connected to the bonding pad BP of the circuit chip 200. In the example of FIG. 8, the areas of the respective bonding pads BP of the memory chip 100 and the circuit chip 200 on the bonding plane are substantially equal. In such a case, in a case where copper is used for the bonding pad BP, the copper of the bonding pad BP of the memory chip 100 and the copper of the bonding pad BP of the circuit chip 200 are integrated, and it may be difficult to confirm the boundary between the copper. However, bonding boundary can be confirmed by distortion of a shape due to positional deviation of bonding between the bonding pads BP and positional deviation of a copper barrier metal (occurrence of a discontinuous portion on a side surface).

In a case where the bonding pad BP is formed by a damascene method, each side surface has a tapered shape. Therefore, in the bonding portion where the bonding pads BP are bonded to each other, the side wall does not have a linear shape in the cross section along the Z direction, and the cross section has a non-rectangular shape.

In addition, in a case where the bonding pads BP are attached to each other, a bottom surface, a side surface, and an upper surface of copper forming the bonding pads BP are covered with the barrier metal. On the other hand, in a general wiring layer using copper, an insulating layer (silicon nitride, silicon carbonitride, or the like) having a function of preventing oxidation of copper is provided on the upper surface of copper, and no barrier metal is provided. Therefore, it is possible to distinguish from a general wiring layer even if no positional deviation of bonding occurs.

### 1.1.4.3 Cross-Sectional Structure

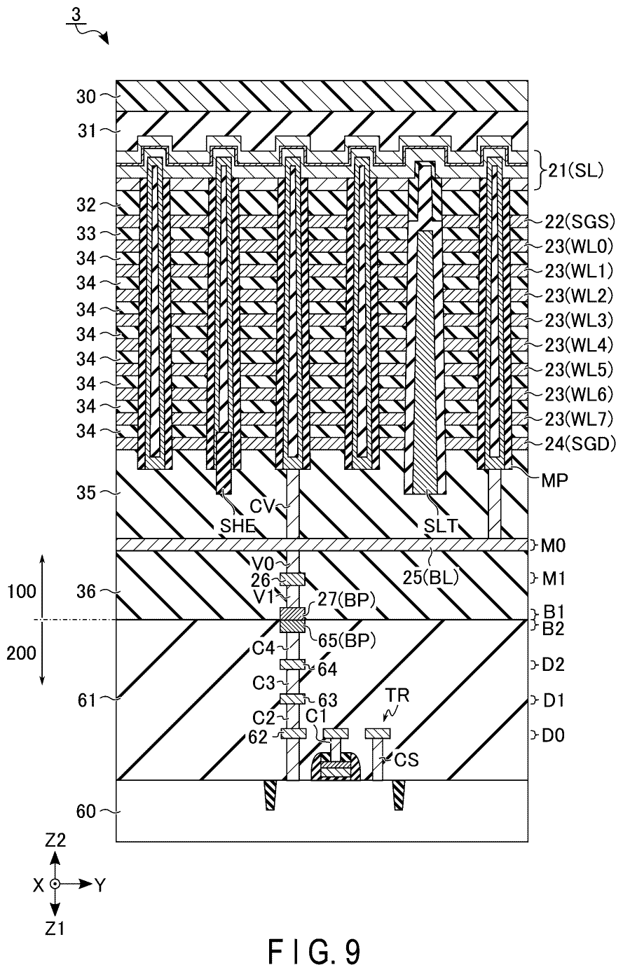

FIG. 9 is a cross-sectional view illustrating an example of a cross-sectional structure of the memory device according to the first embodiment. In FIG. 9, the Z2 direction corresponds to the upper side of the drawing.

As illustrated in FIG. 9, the memory device 3 further includes conductive layers 26 and 27, a protective layer 30, and contacts V0 and V1 in the memory chip 100. The memory device 3 includes a substrate 60, an insulating layer 61, conductive layers 62, 63, 64, and 65, a transistor TR, and contacts CS, C1, C2, C3, and C4 in the circuit chip 200.

First, the memory chip 100 will be described.

The protective layer 30 is provided on the surface of the insulating layer 31 on the Z2 direction side. The protective layer 30 is a layer corresponding to the surface of the memory device 3, and includes, for example, a resin material such as polyimide. In a region not illustrated, a part of the protective layer 30 is removed. Then, the portion from which the protective layer 30 is removed is provided with a power supply pad for electrical connection with the outside.

On a surface of the conductive layer 25 on the Z1 direction side, the contact V0 is provided. On the surface of the contact V0 on the Z1 direction side, the conductive layer 26 is provided.

On a surface of the conductive layer 26 on the Z1 direction side, the contact V1 is provided. On the surface of the contact V1 on the Z1 direction side, the conductive layer 27 is provided. The conductive layer 27 functions as a bonding pad BP on the bonding plane of the memory chip 100 with the circuit chip 200. The conductive layers 26 and 27 and the contacts V0 and V1 are covered with the insulating layer 36. The layers on which the conductive layers 26 and 27 are provided are also referred to as a layer M1 and a bonding layer B1, respectively.

Next, the circuit chip 200 will be described.

The substrate 60 is a silicon substrate. On the surface of the substrate 60 on the Z2 direction side, the insulating layer 61 is provided. In the substrate 60 and the insulating layer 61, the transistor TR is provided.

The transistor TR has a structure constituting various circuits provided in the circuit chip 200. In the example of FIG. 9, the transistor TR corresponds to a circuit (for example, a transistor in the sense amplifier module 16) connected to the bit line BL.

On a surface of the gate electrode of the transistor TR on the Z2 direction side, the contact C1 is provided. On a surface on the Z2 direction side of a region functioning as a source or a drain of the transistor TR in the substrate 60, the contact CS is provided. On the surface of each of the contacts CS and C1 on the Z2 direction side, the conductive layer 62 is provided. The contacts CS and C1 and the conductive layer 62 contain, for example, tungsten.

On a surface of the conductive layer 62 on the Z2 direction side, the contact C2 is provided. On the surface of the contact C2 on the Z2 direction side, the conductive layer 63 is provided. On a surface of the conductive layer 63 on the Z2 direction side, the contact C3 is provided. On the surface of the contact C3 on the Z2 direction side, the conductive layer 64 is provided. On a surface of the conductive layer 64 on the Z2 direction side, the contact C4 is provided. On the surface of the contact C4 on the Z2 direction side, the conductive layer 65 is provided. The conductive layer 65 is in contact with the corresponding conductive layer 27 and functions as the bonding pad BP on the bonding surface of the circuit chip 200 to the memory chip 100. The conductive layers 62, 63, 64, and 65 and the contacts CS, C1, C2, C3, and C4 are covered by the insulating layer 61. The layers in which the conductive layers 62, 63, 64, and 65 are provided are also referred to as layers D0, D1, and D2, and a bonding layer B2, respectively.

### 1.2 Manufacturing Method

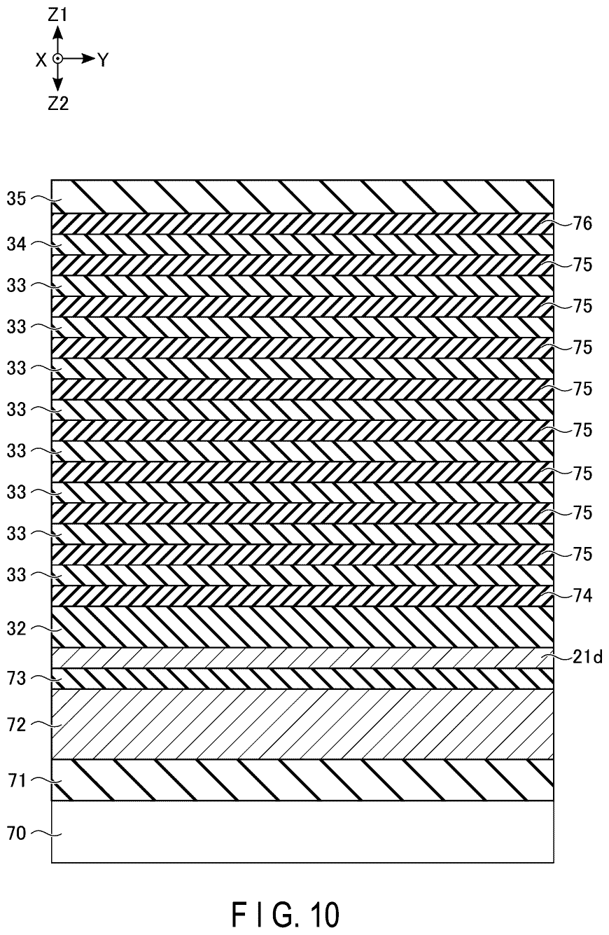

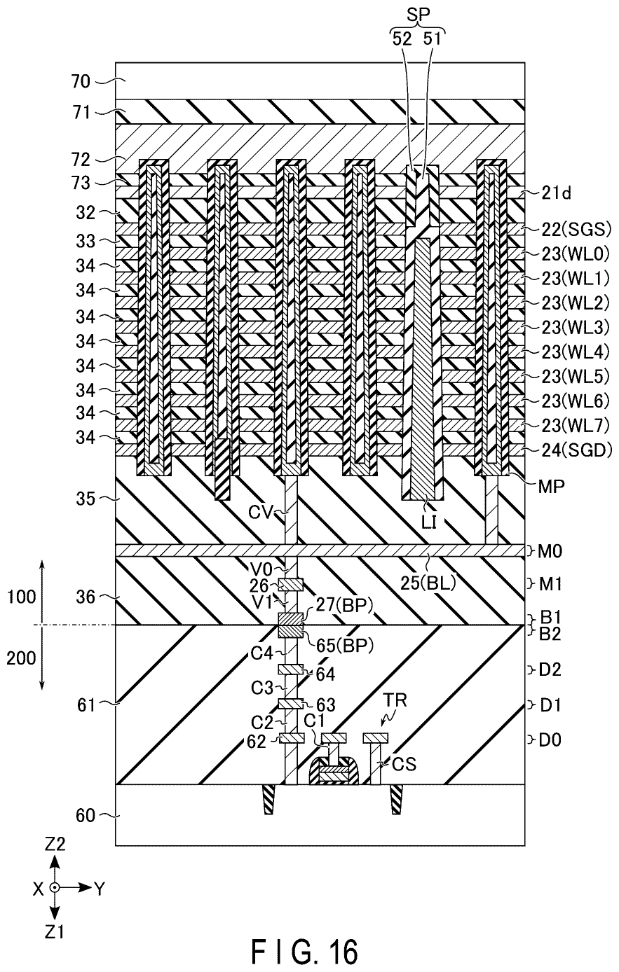

FIGS. 10 to 18 are diagrams illustrating an example of a structure in a process of manufacturing the memory device according to the first embodiment. Among these, FIGS. 10 to 15 are cross-sectional views in the process of manufacturing the memory cell array 10 in the memory chip 100 before bonding, and correspond to FIG. 5. FIGS. 16 to 18 are cross-sectional views in the process of manufacturing the memory chip 100 and the circuit chip 200 after bonding, and correspond to FIG. 9.

The memory chip 100 and the circuit chip 200 are separately manufactured. Hereinafter, a method of manufacturing the memory chip 100 will be focused.

First, as illustrated in FIG. 10, an insulating layer 71 is provided on a surface of a substrate 70 on the Z1 direction side. The substrate 70 is a substrate of the memory chip 100, and includes, for example, silicon. The insulating layer 71 includes, for example, silicon oxide.

On the surface of the insulating layer 71 on the Z1 direction side, the semiconductor layer 72 is provided. On the surface of the semiconductor layer 72 on the Z1 direction side, the insulating layer 73 is provided. On the surface of the insulating layer 73 on the Z1 direction side, the semiconductor layer 21d is provided. The semiconductor layer 72 includes, for example, polysilicon. The insulating layer 73 includes, for example, silicon oxide.

Then, a stacked structure corresponding to the stacked wiring structure is provided on the Z1 direction side with respect to the semiconductor layer 21d. Specifically, on the surface of the semiconductor layer 21d on the Z1 direction side, the insulating layer 32 and the sacrificial layer 74 are provided in this order. On the surface of the sacrificial layer 74 on the Z1 direction side, the insulating layers 33 and the sacrificial layers 75 are alternately stacked. On the surface of the uppermost sacrificial layer 75 on the Z1 direction side, the insulating layer 34 and the sacrificial layer 76 are provided in this order. On the surface of the sacrificial layer 76 on the Z1 direction side, the insulating layer 35 is provided. The sacrificial layers 74 to 76 includes, for example, silicon nitride.

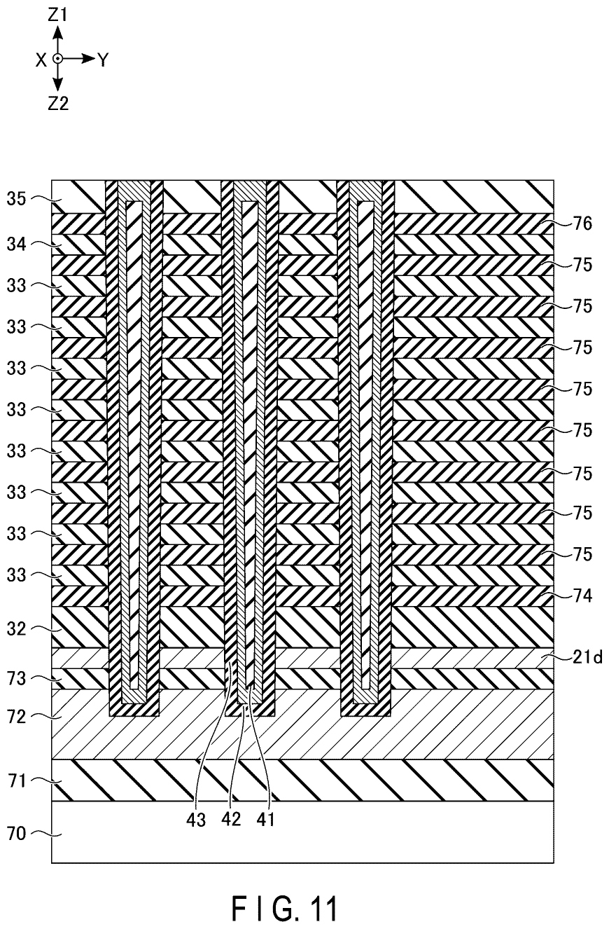

Next, as illustrated in FIG. 11, a plurality of holes (not illustrated) is provided in a region where the memory pillars MP are to be provided in the stacked structure. Bottom surfaces of the holes reach the semiconductor layer 72, for example. Then, the stacked film 43, the semiconductor film 42, and the core film 41 are formed in this order in each hole, and each hole is filled. As a result, a structure corresponding to the memory pillar MP is formed. In the structure corresponding to the memory pillar MP, the stacked film 43 covers the end portion of the semiconductor film 42 on the Z2 direction side.

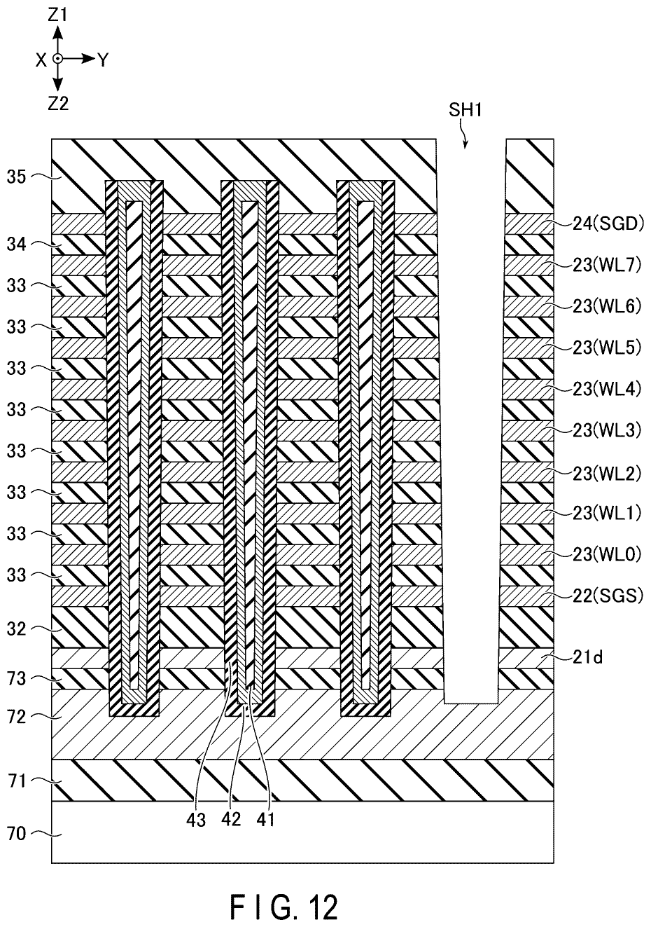

Next, as illustrated in FIG. 12, a groove SH1 is formed in a region where the member SLT is to be provided. The bottom surface of the groove SH1 reaches the semiconductor layer 72, for example. Then, the replacement process of the stacked structure is executed via the groove SH1.

In the replacement process of the stacked structure, the sacrificial layers 74, 75, and 76 are selectively removed via the groove SH1 by wet etching using thermal phosphoric acid or the like. Then, the conductor is embedded in the space from which the sacrificial layers 74, 75, and 76 have been removed via the groove SH1. Thereafter, the conductor formed inside the groove SH1 is removed by an etch-back process. As a result, the conductor formed inside the groove SH1 is separated into a plurality of conductive layers. As a result, the wiring layer 22 functioning as the select gate line SGS, the wiring layers 23 each functioning as the word line WL, and the wiring layer 24 functioning as the select gate line SGD are formed. The wiring layers 22, 23, and 24 formed in this step may contain a barrier metal. In this case, in the formation of the conductor after the removal of the sacrificial layers 74, 75, and 76, for example, tungsten is formed after titanium nitride is deposited as a barrier metal.

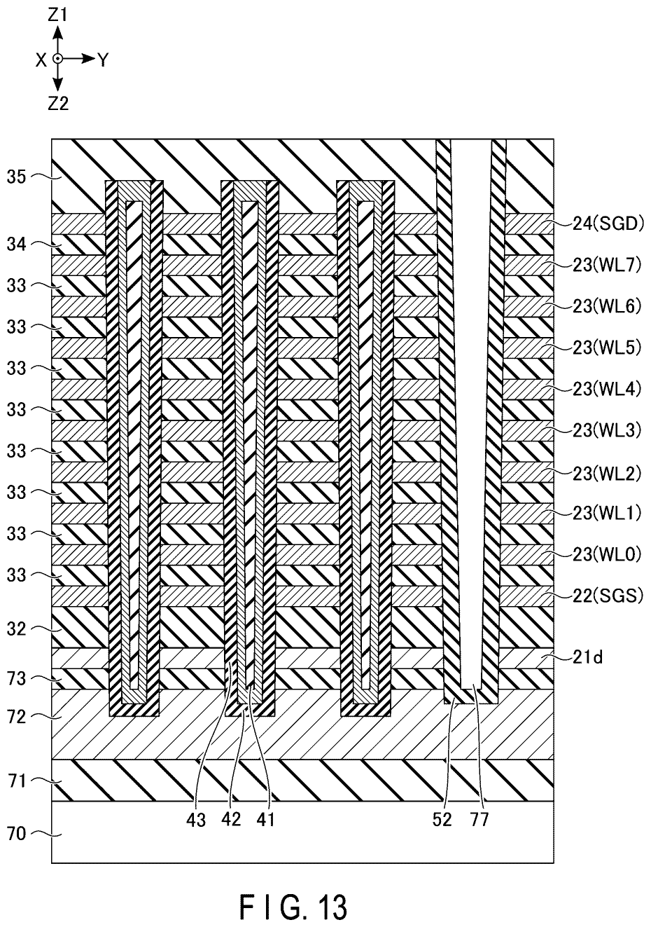

Next, as illustrated in FIG. 13, the insulating film 52 and a sacrificial film 77 are formed in this order in the groove SH1, and the groove SH1 is filled. The sacrificial film 77 includes, for example, a spin-on carbon (SOC).

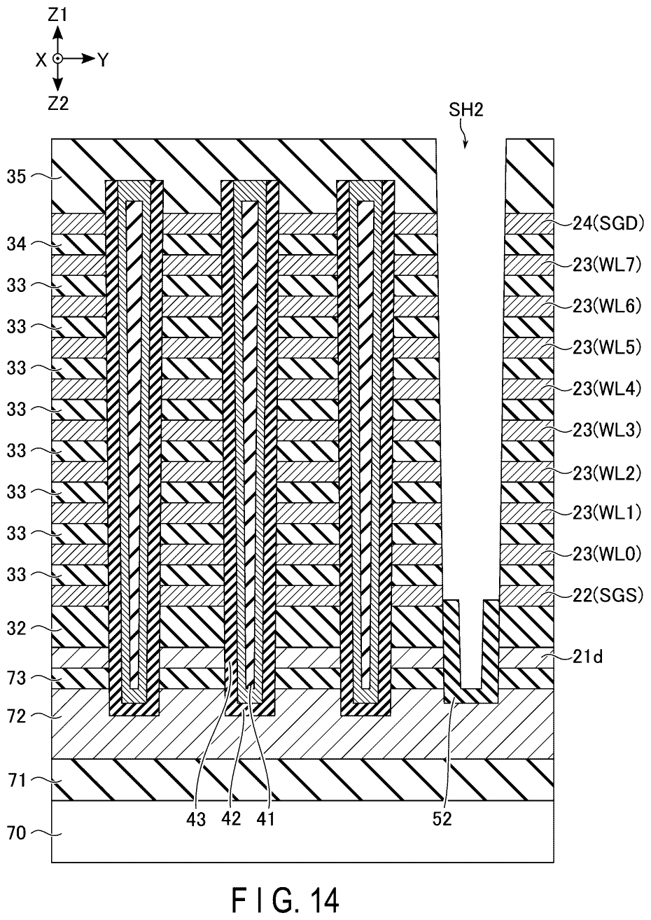

Next, as illustrated in FIG. 14, for example, a groove SH2 is formed in a region where the member SLT is to be provided. Specifically, first, a part of the sacrificial film 77 is etched back so as to leave a portion corresponding to the bottom portion of the insulating film 51. Then, the insulating film 52 is removed to substantially the same height as the surface on the Z1 direction side of the sacrificial film 77 remaining after the etch-back process. Thereafter, the sacrificial film 77 remaining after the etch-back process is removed to form the groove SH2.

The wiring layer 24 and at least one of the wiring layers 23 are exposed inside the groove SH2. The wiring layer 22 may be partially exposed, but is preferably not completely exposed. In other words, the surface on the Z1 direction side of the insulating film 52 is preferably located on the Z1 direction side with respect to the surface on the Z2 direction side of the wiring layer 22.

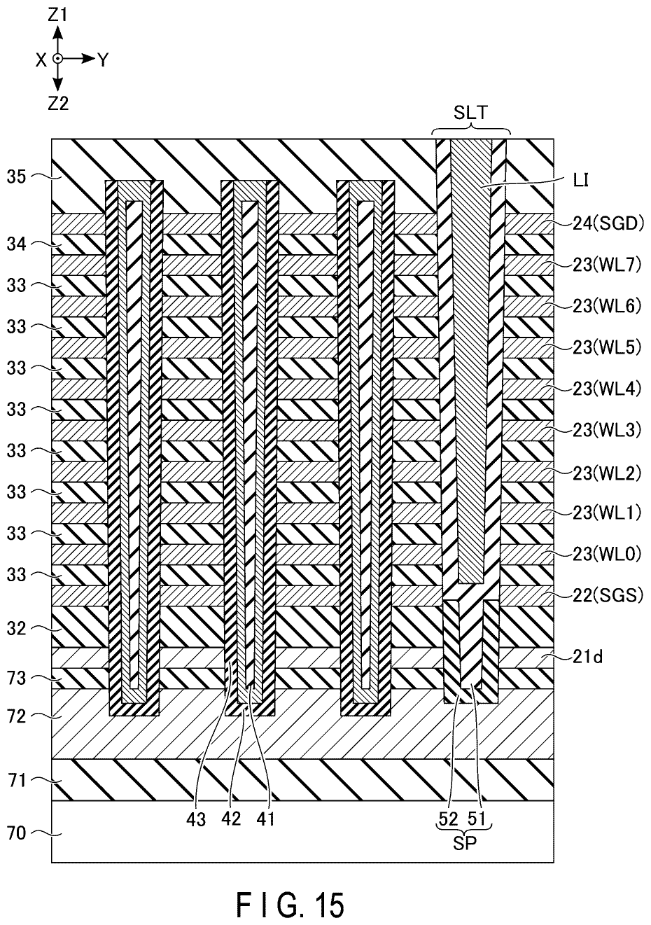

Next, as illustrated in FIG. 15, the insulating film 51 and the filling material LI are formed in this order in the groove SH2, and the groove SH2 is filled. The width of the groove SH2 at a height at which the insulating film 52 remains is smaller than twice the film thickness “a” of the insulating film 51. Therefore, a portion of the groove SH2 at the height where the insulating film 52 remains is closed by the insulating film 51. On the other hand, the width “b” of the portion of the groove SH2 on the Z1 direction side with respect to the insulating film 52 is larger than twice the film thickness “a” of the insulating film 51. Therefore, a portion of the groove SH2 on the Z1 direction side with respect to the insulating film 52 is not closed by the insulating film 51. Then, a portion of the groove SH2 that is not closed by the insulating film 51 is filled with the filling material LI. As described above, the member SLT is formed.

Thereafter, a structure on the Z1 direction side from the member SHE and the stacked wiring structure is formed, and the manufacturing of the memory chip 100 is completed.

Next, as illustrated in FIG. 16, the memory chip 100 and the circuit chip 200 are bonded together.

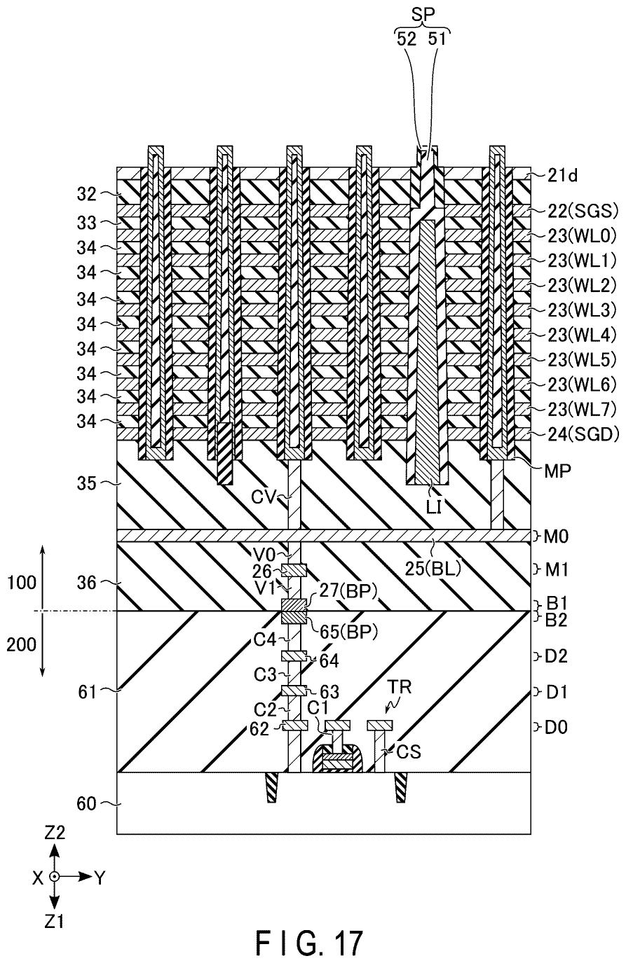

Next, as illustrated in FIG. 17, the substrate 70, the insulating layer 71, and the semiconductor layer 72 are removed. Then, a portion of the insulating layer 73 and the stacked film 43 on the Z2 direction side with respect to the semiconductor layer 21d is removed. As a result, a portion of the semiconductor film 42 on the Z2 direction side with respect to the semiconductor layer 21d is exposed. In a case where the insulating layer 73 and the stacked film 43 are removed, a portion of the insulating film 52 on the Z2 direction side with respect to the semiconductor layer 21d is also partially removed.

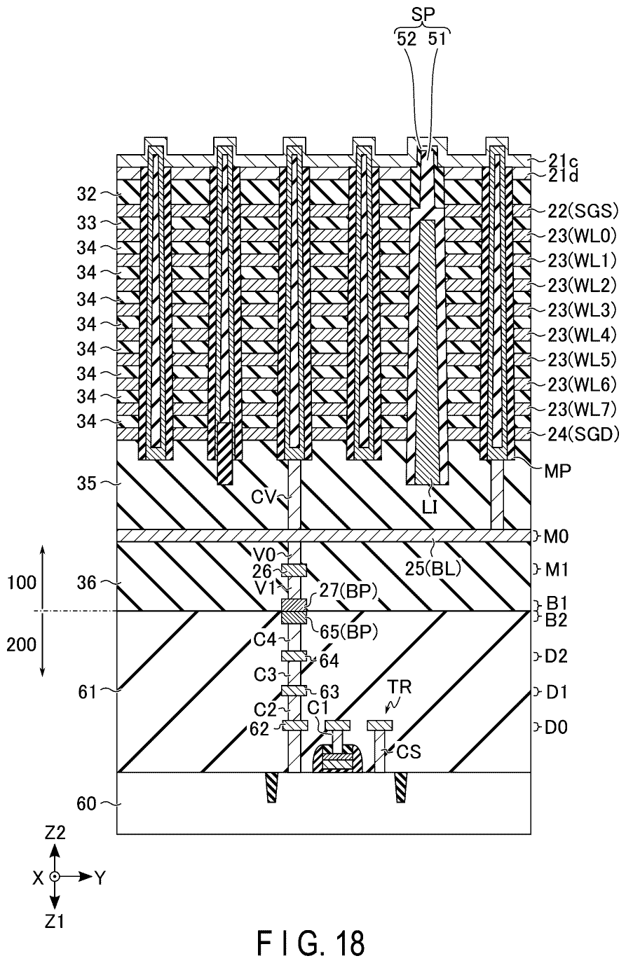

Next, as illustrated in FIG. 18, a semiconductor is provided so as to cover the semiconductor layer 21d, the semiconductor film 42, and the insulating film 52. The semiconductor includes, for example, amorphous silicon. After the film formation, impurities such as arsenic are implanted into the semiconductor. Then, the semiconductor is heated and crystallized by laser annealing processing, for example. As a result, the semiconductor layer 21c having conductivity is formed.

On the surface of the semiconductor layer 21c on the Z2 direction side, conductive layers 21b and 21a are laminated in this order. As a result, the wiring layer 21 functioning as the source line SL is formed.

Thereafter, the insulating layer 31, the protective layer 30, and the like are formed on the Z2 direction side with respect to the wiring layer 21. As described above, the memory device 3 is formed.

### 1.3 Effects According to First Embodiment

According to the first embodiment, the yield of the memory device 3 can be improved. This effect will be described below.

The filling material LI extends in the XZ plane on the wiring layers 22 side from the surface on the semiconductor layer 21d side of the wiring layer 23. The insulating material SP is provided between the filling material LI, and the semiconductor layer 21d, the wiring layer 22, each of the wiring layers 23, and the wiring layer 24, and has a lower thermal conductivity than the filling material LI. With this configuration, the insulating material SP having a sufficient thickness can be interposed between the filling material LI and the semiconductor layer 21c. Therefore, in a case where the semiconductor layer 21c is heated by the laser annealing treatment, it is possible to suppress that heat is deprived by the filling material LI having a relatively high thermal conductivity, and the semiconductor layer 21c in the vicinity of the member SLT is not sufficiently crystallized. Therefore, characteristic deterioration of the wiring layer 21 in the vicinity of the member SLT can be suppressed.

The width “b” of the member SLT in the Y direction is longer than twice the thickness “a” of the portion between the filling material LI and each of the wiring layers 23 in the insulating material SP (the insulating film 51). The distance “c” in the Z direction of the portion of the insulating material SP closer to the semiconductor layer 21d than the filling material LI is longer than the thickness “a”. As described above, the film thickness of the insulating material SP on the semiconductor layer 21d side with respect to the filling material LI is significantly larger than the film thickness of the insulating material SP on the side portion of the filling material LI. As a result, the amount of heat transferred to the filling material LI in the heat generated by the laser annealing treatment can be reduced. Therefore, crystallization of the semiconductor layers 21c and 21d in the vicinity of the member SLT can be promoted.

In addition, the filling material LI has a Young's modulus higher than that of the insulating material SP. As a result, it is possible to increase the flexural strength of the memory cell array 10 as compared with the case where the member SLT includes only the insulating material SP.

### 1.4 Modification of First Embodiment

Various modifications can be applied to the above-described first embodiment.

In the first embodiment described above, the case where the insulating material SP is formed of the two types of insulating films 51 and 52 has been described, but the present invention is not limited thereto. The insulating material SP may be formed of one type of insulating film.

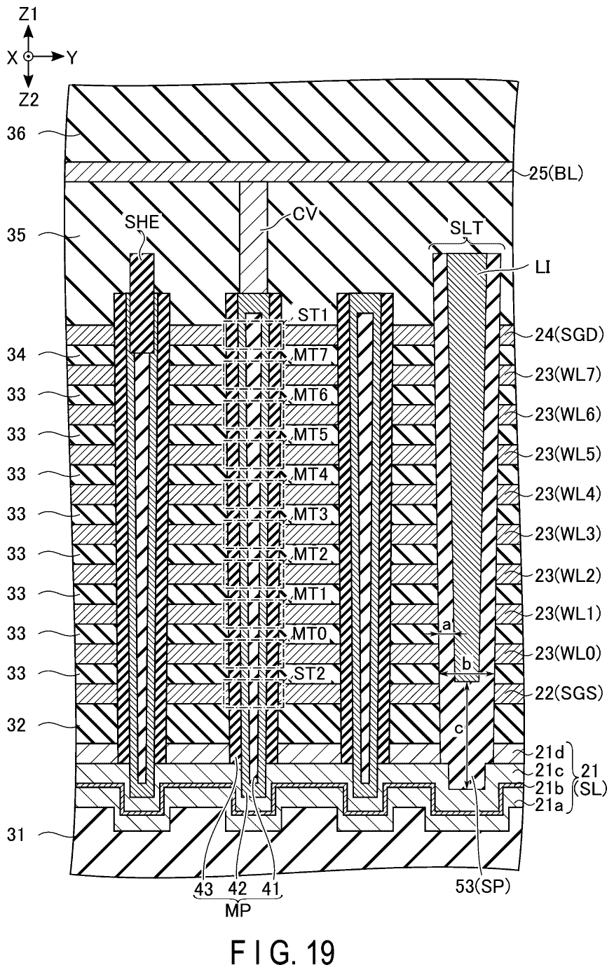

FIG. 19 is a cross-sectional view illustrating an example of a cross-sectional structure of a memory cell array included in a memory device according to a modification of the first embodiment. FIG. 19 corresponds to FIG. 5 in the first embodiment.

As illustrated in FIG. 19, according to the modification of the first embodiment, an insulating material SP includes an insulating film 53 instead of insulating films 51 and 52.

The insulating film 53 is an insulator that covers the side surface and an end surface on the Z2 direction side of a filling material LI. The insulating film 53 has a portion (bottom portion) extending in the Z direction on the Z2 direction side with respect to the filling material LI. The bottom portion of the insulating film 53 is thicker than the film thickness “a” of the portion covering the side surface of the filling material LI and reaches the semiconductor layer 21c. The insulating film 53 contains silicon oxide, for example. In a case where the filling material LI has conductivity, the insulating film 53 electrically insulates the filling material LI from each of the wiring layers 22 to 24.

In the member SLT including the filling material LI and the insulating material SP described above, the width “b” of the member SLT in the Y direction is larger than twice the film thickness “a” of the portion covering the side surface of the filling material LI in the insulating film 53. The distance “c” from the end surface on the Z2 direction side of the insulating material SP to the end surface on the Z2 direction side of the filling material LI is larger than the film thickness “a” of the portion on the Z1 direction side than the bottom portion of the insulating film 53.

Such an insulating film 53 can be realized by using a film forming process (bottom-up filling process) of making the thickness of the film formed on the bottom surface of the groove SH1 thicker than the film formed on the side surface.

Also in the above configuration, similarly to the first embodiment, the film thickness of the insulating material SP on the semiconductor layer 21d side with respect to the filling material LI can be made significantly larger than the film thickness of the insulating material SP on the side portion of the filling material LI. As a result, the amount of heat transferred to the filling material LI in the heat generated by the laser annealing treatment can be reduced. Therefore, crystallization of the semiconductor layers 21c and 21d in the vicinity of the member SLT can be promoted.

### 2. Second Embodiment

A memory device according to a second embodiment will be described. The second embodiment is different from the first embodiment in that the end portion of the member SLT on the Z2 direction side does not reach the wiring layer 21. In the following description, a configuration and a manufacturing method different from those of the first embodiment will be mainly described. Description of the same configuration and manufacturing method as those of the first embodiment will be omitted as appropriate.

### 2.1 Configuration

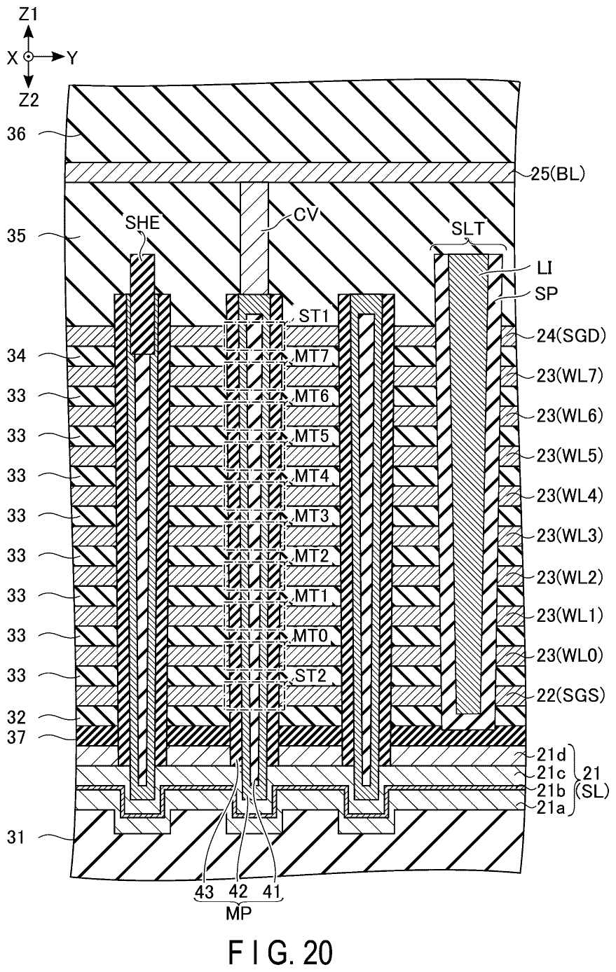

FIG. 20 is a cross-sectional view illustrating an example of a cross-sectional structure of a memory cell array included in a memory device according to the second embodiment. FIG. 20 corresponds to FIG. 5 in the first embodiment.

As illustrated in FIG. 20, in the second embodiment, a memory cell array 10 further includes a stop film 37.

An end portion of a member SLT on the Z2 direction side does not reach a wiring layer 21. Therefore, in each of conductive layers 21a and 21b and a semiconductor layer 21c, a region including a portion overlapping the member SLT as viewed in the Z direction has a flat shape. On the other hand, in the region overlapping the memory pillar MP as viewed in the Z direction, the surfaces of the conductive layers 21a and 21b and the semiconductor layer 21c on the Z2 direction side are formed to have unevenness as in the first embodiment.

The stop film 37 is provided on the entire surface of a semiconductor layer 21d on the Z1 direction side. The stop film 37 has a function of preventing the progress of etching in a case of forming a groove corresponding to the member SLT. The stop film 37 is, for example, an insulator containing at least one substance selected from aluminum oxide (Al₂O₃), silicon carbide (SiC), and carbon (C). The stop film 37 has a film type different from that of an insulating layer 32.

The insulating layer 32 is provided on the surface of the stop film 37 on the Z1 direction side. The structure on the Z1 direction side with respect to the insulating layer 32 is the same as that of the first embodiment.

The filling material LI intersects the wiring layers 23 and 24 and the insulating layers 33 to 35. The filling material LI may or may not intersect the wiring layer 22.

An insulating material SP covers the side surface and the end surface on the Z2 direction side of the filling material LI. The end on the Z2 direction side of the insulating material SP is located in the stop film 37.

### 2.2 Manufacturing Method

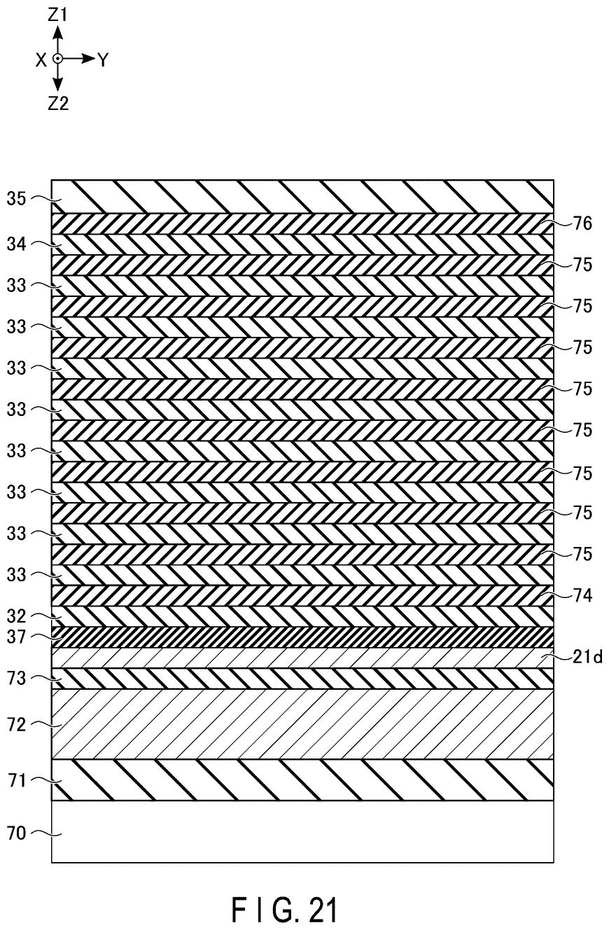

FIGS. 21, 22, 23, and 24 are diagrams illustrating an example of a structure in a process of manufacturing the memory device according to the second embodiment. FIGS. 21, 22, 23, and 24 are cross-sectional views in the process of manufacturing the memory cell array 10 in the memory chip 100, and correspond to FIG. 20.

First, as illustrated in FIG. 21, the insulating layer 71, the semiconductor layer 72, the insulating layer 73, the semiconductor layer 21d, and the stop film 37 are provided in this order on the surface of the substrate 70 on the Z1 direction side.

Then, a stacked structure corresponding to the stacked wiring structure is provided on the Z1 direction side with respect to the stop film 37. Specifically, the insulating layer 32 and the sacrificial layer 74 are provided in this order on the surface of the stop film 37 on the Z1 direction side. On the surface of the sacrificial layer 74 on the Z1 direction side, the insulating layers 33 and the sacrificial layers 75 are alternately stacked. On the surface of the uppermost sacrificial layer 75 on the Z1 direction side, the insulating layer 34 and the sacrificial layer 76 are provided in this order. On the surface of the sacrificial layer 76 on the Z1 direction side, the insulating layer 35 is provided.

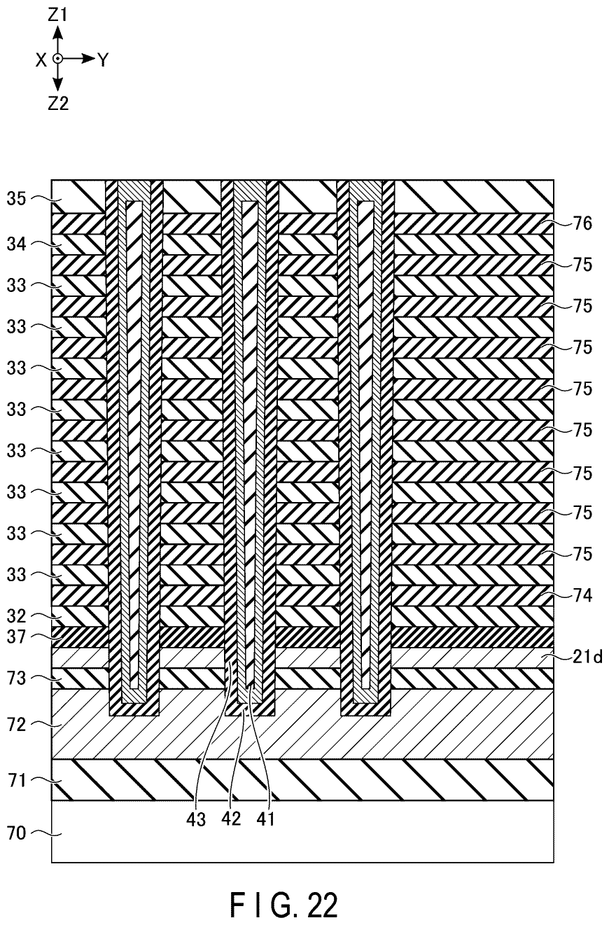

Next, as illustrated in FIG. 22, a plurality of holes (not illustrated) is provided in a region where the memory pillars MP are to be provided in the stacked structure. The bottom surfaces of the holes reach, for example, the stop film 37. Subsequently, the bottom of each hole is further etched. As a result, the bottom surfaces of the holes reach the semiconductor layer 72.

Thereafter, the stacked film 43, the semiconductor film 42, and the core film 41 are formed in this order in each hole, and each hole is filled. As a result, a structure corresponding to the memory pillar MP is formed. In the structure corresponding to the memory pillar MP, the stacked film 43 covers the end portion of the semiconductor film 42 on the Z2 direction side.

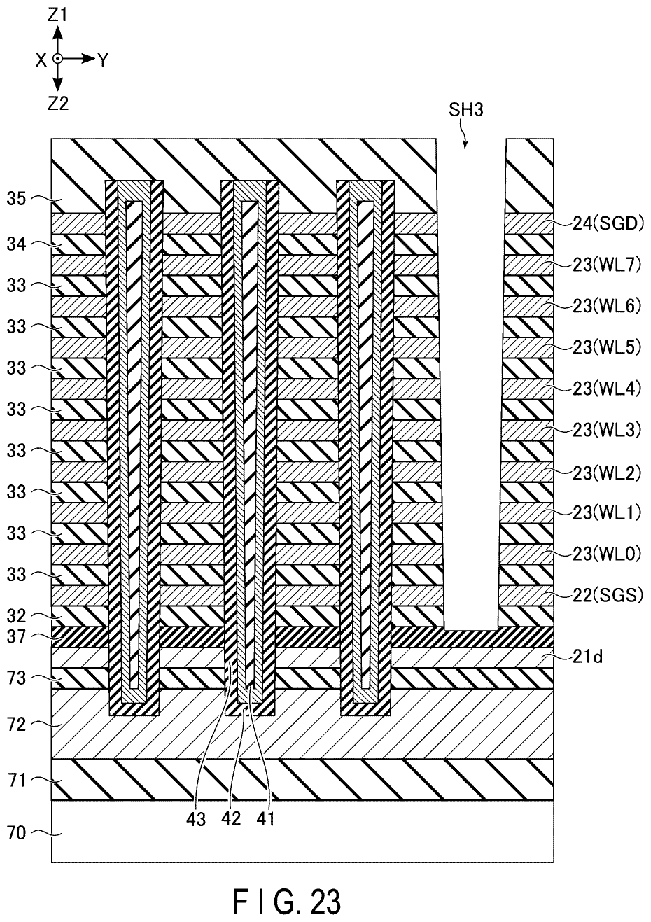

Next, as illustrated in FIG. 23, a groove SH3 is formed in a region where the member SLT is to be provided. The bottom surface of the groove SH3 reaches, for example, the stop film 37. Then, the replacement process of the stacked structure is executed via the groove SH3. As a result, the wiring layers 22, 23, and 24 are formed.

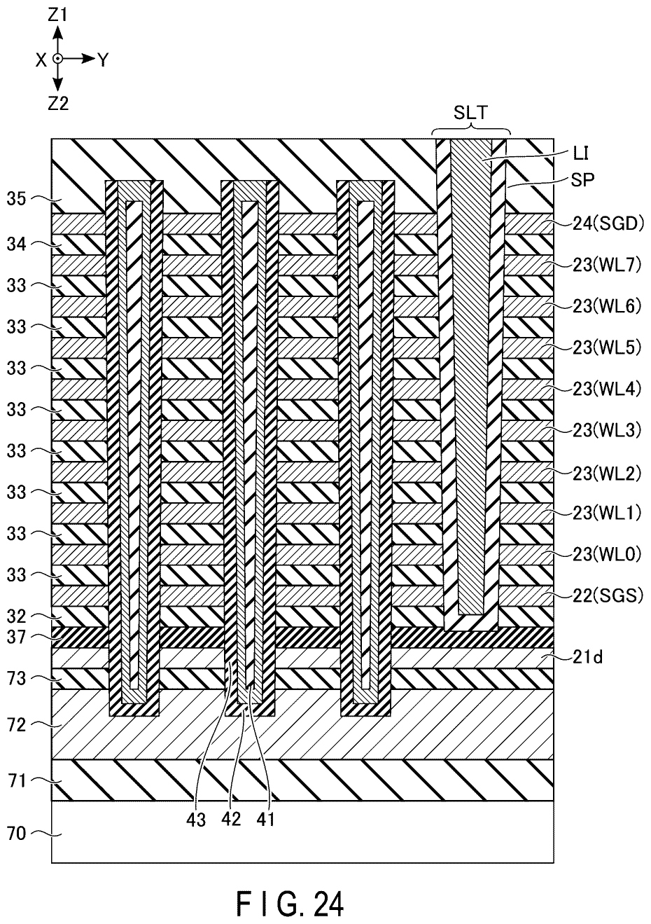

Next, as illustrated in FIG. 24, the insulating material SP and the filling material LI are formed in this order in the groove SH3, and the groove SH3 is filled. As a result, the member SLT is formed.

Thereafter, a structure on the Z1 direction side from the member SHE and the stacked wiring structure is formed, and the manufacturing of the memory chip 100 is completed. The subsequent steps are the same as those in the first embodiment.

### 2.3 Effects According to Second Embodiment

According to the second embodiment, the stop film 37 is provided between the insulating material SP and the semiconductor layer 21d, and extends in the XY plane so as to enclose the insulating material SP as viewed in the Z direction. The stop film 37 contains at least one substance selected from aluminum oxide (Al₂O₃), silicon carbide (SiC), and carbon (C). Thus, in a case where the member SLT is formed, etching on the stacked structure can be stopped by the stop film 37. Therefore, it is possible to prevent the filling material LI from being exposed in a case where the semiconductor film 42 of the memory pillar MP is exposed. Therefore, in a case where the semiconductor layer 21c is heated by the laser annealing treatment, it is possible to suppress that heat is deprived by the filling material LI having a relatively high thermal conductivity, and the semiconductor layer 21c in the vicinity of the member SLT is not sufficiently crystallized. In addition, crystallization of the semiconductor layer 21d in the vicinity of the member SLT can be promoted.

### 2.4 Modification of Second Embodiment

Various modifications can be applied to the second embodiment described above.

### 2.4.1 First Modification of Second Embodiment

According to the second embodiment described above, the case where the stop film 37 is provided between the semiconductor layer 21d and the insulating layer 32 has been described, but the present invention is not limited thereto. The stop film 37 may be provided between the insulating layer 32 and the wiring layer 22.

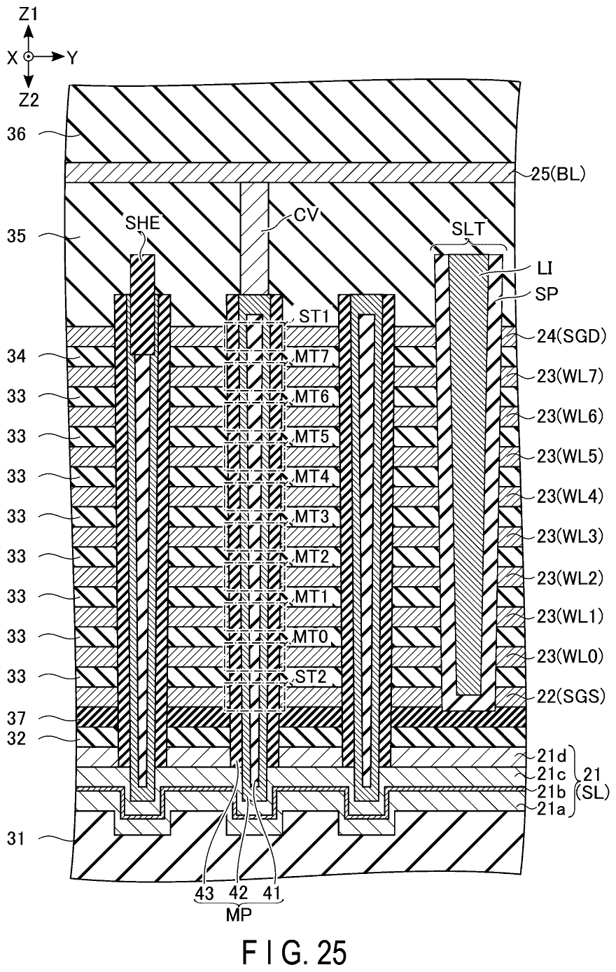

FIG. 25 is a cross-sectional view illustrating an example of a cross-sectional structure of a memory cell array included in a memory device according to a first modification of the second embodiment. FIG. 25 corresponds to FIG. 20 in the second embodiment.

As illustrated in FIG. 25, an insulating layer 32 is provided on a surface of a semiconductor layer 21d on the Z1 direction side. A stop film 37 is provided on the entire surface of the insulating layer 32 on the Z1 direction side. On the surface of the stop film 37 on the Z1 direction side, a wiring layer 22 is provided. The structure on the Z1 direction side with respect to the wiring layer 22 is the same as that of the second embodiment.

In the above configuration, the end on the Z2 direction side of an insulating material SP is located in the stop film 37. As a result, an insulator including the insulating layer 32, the insulating material SP, and the stop film 37 can be interposed between a filling material LI and a wiring layer 21. Therefore, similarly to the second embodiment, it is possible to reduce the amount of heat transferred to the filling material LI in the heat generated by the laser annealing treatment. Therefore, crystallization of the semiconductor layers 21c and 21d in the vicinity of the member SLT can be promoted.

### 2.4.2 Second Modification of Second Embodiment

In the second embodiment and the first modification of the second embodiment described above, the case where the stop film 37 and the insulating layer 32 are stacked between the semiconductor layer 21d and the wiring layer 22 has been described, but the present invention is not limited thereto. The stop film 37 may be provided between the semiconductor layer 21d and the wiring layer 22, and the insulating layer 32 may not be provided.

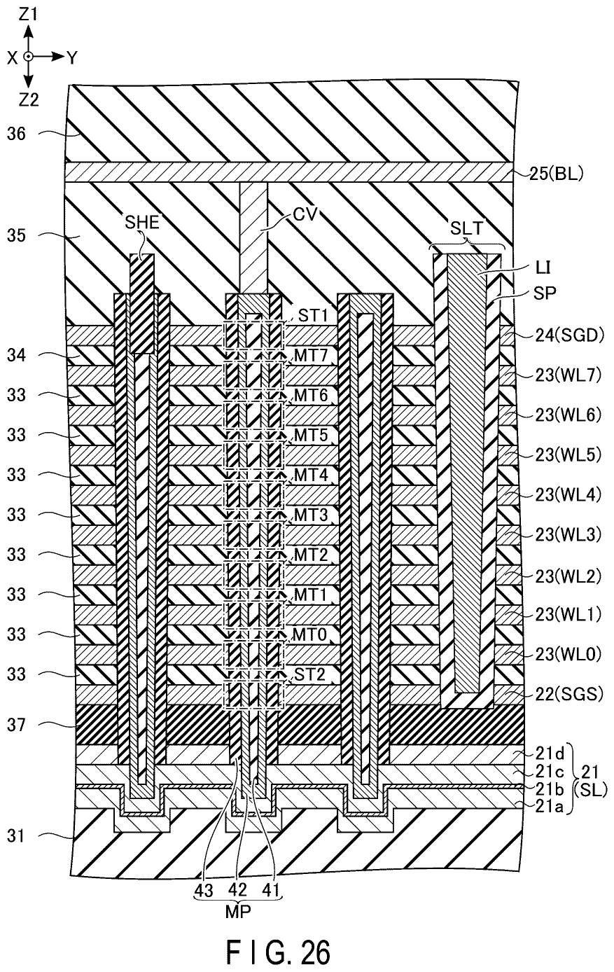

FIG. 26 is a cross-sectional view illustrating an example of a cross-sectional structure of a memory cell array included in a memory device according to a second modification of the second embodiment. FIG. 26 corresponds to FIG. 20 in the second embodiment.

As illustrated in FIG. 26, a stop film 37 is provided on the entire surface of a semiconductor layer 21d on the Z1 direction side. On the surface of the stop film 37 on the Z1 direction side, a wiring layer 22 is provided. The structure on the Z1 direction side with respect to the wiring layer 22 is the same as that of the second embodiment.

In the above configuration, the end on the Z2 direction side of an insulating material SP is located in the stop film 37. As a result, an insulator including an insulating material SP and the stop film 37 can be interposed between a filling material LI and a wiring layer 21. Therefore, similarly to the second embodiment, it is possible to reduce the amount of heat transferred to the filling material LI in the heat generated by the laser annealing treatment. Therefore, crystallization of the semiconductor layers 21c and 21d in the vicinity of the member SLT can be promoted.

### 3. Third Embodiment

Next, a memory device according to a third embodiment will be described. The third embodiment is different from the second embodiment in that a stop film is provided in the same layer as the insulating layer 32. In the following description, a configuration and a manufacturing method different from those of the second embodiment will be mainly described. Description of the same configuration and manufacturing method as those of the second embodiment will be omitted as appropriate.

### 3.1 Configuration

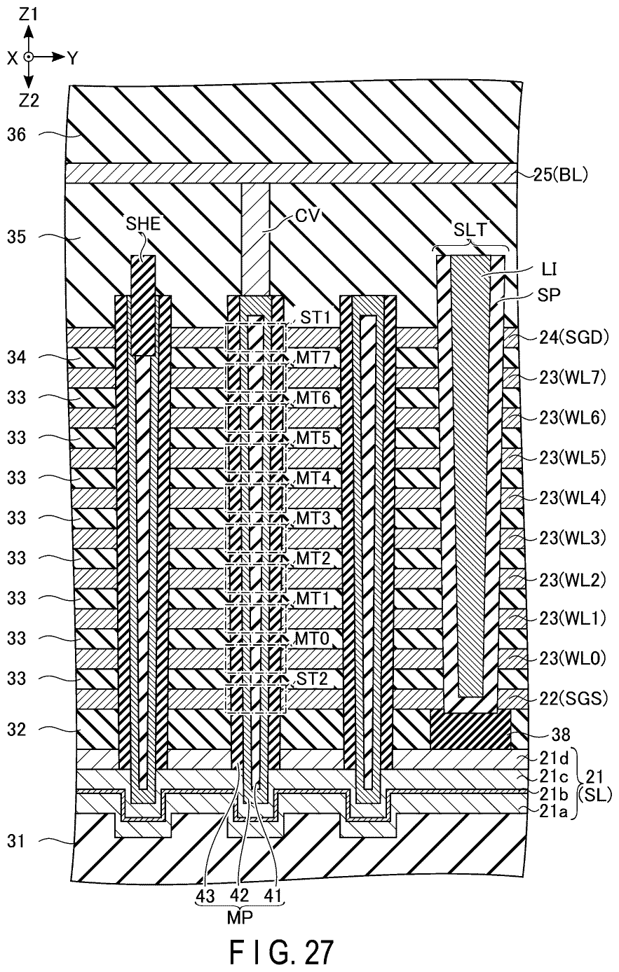

FIG. 27 is a cross-sectional view illustrating an example of a cross-sectional structure of a memory cell array included in a memory device according to a third embodiment. FIG. 27 corresponds to FIG. 20 in the second embodiment.

As illustrated in FIG. 27, in the third embodiment, a memory cell array 10 includes a stop film 38 instead of the stop film 37.

As in the second embodiment, an end portion of a member SLT on the Z2 direction side does not reach a wiring layer 21. Therefore, in each of conductive layers 21a and 21b and a semiconductor layer 21c, a region including a portion overlapping the member SLT as viewed in the Z direction has a flat shape.

The stop film 38 is provided in a region including a portion overlapping the member SLT as viewed in the Z direction on the surface of the semiconductor layer 21d on the Z1 direction side. The stop film 38 has a function of preventing the progress of etching in a case of forming a groove corresponding to the member SLT. The stop film 38 is, for example, an insulator containing at least one substance selected from aluminum oxide (Al₂O₃), silicon carbide (SiC), and carbon (C). The stop film 38 has a film type different from that of the insulating layer 32.

The insulating layer 32 is provided in a region where the stop film 38 is not provided on the surface of the semiconductor layer 21d on the Z1 direction side. The surface of the insulating layer 32 on the Z1 direction side and the surface of the stop film 38 on the Z1 direction side are aligned. In other words, the film thicknesses of the insulating layer 32 and the stop film 38 are substantially equal.

The wiring layer 22 is provided on the surface on the Z1 direction side of each of the insulating layer 32 and the stop film 38. The structure on the Z1 direction side with respect to the wiring layer 22 is the same as that of the second embodiment.

The filling material LI intersects the wiring layers 23 and 24 and the insulating layers 33 to 35. The filling material LI may or may not intersect the wiring layer 22.

An insulating material SP covers the side surface and the end surface on the Z2 direction side of the filling material LI. The end on the Z2 direction side of the insulating material SP is located in the stop film 38.

### 3.2 Manufacturing Method

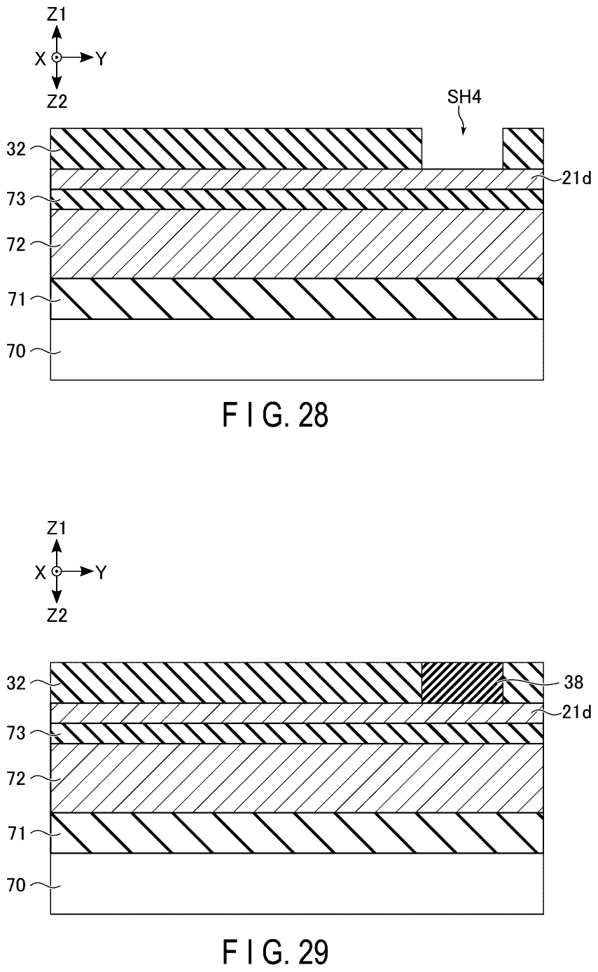

FIGS. 28, 29, 30, 31, and 32 are diagrams illustrating an example of a structure in the process of manufacturing the memory device according to the third embodiment. FIGS. 28, 29, 30, 31, and 32 are cross-sectional views in the process of manufacturing the memory cell array 10 in a memory chip 100, and correspond to FIG. 27.

First, as illustrated in FIG. 28, the insulating layer 71, the semiconductor layer 72, the insulating layer 73, the semiconductor layer 21d, and the insulating layer 32 are provided in this order on the surface of the substrate 70 on the Z1 direction side.

Then, a region of the insulating layer 32 where the stop film 38 is to be provided is removed by, for example, anisotropic etching. As a result, a groove SH4 is formed. The semiconductor layer 21d is exposed on the bottom surface of the groove SH4.

Next, as illustrated in FIG. 29, the groove SH4 is filled by the stop film 38. A portion of the stop film 38 provided outside the groove SH4 is etched back. As a result, the film thicknesses of the insulating layer 32 and the stop film 38 are equalized.

Then, a stacked structure corresponding to the stacked wiring structure is provided on the Z1 direction side with respect to the insulating layer 32 and the stop film 38. Specifically, a sacrificial layer 74 is provided on the surfaces of the insulating layer 32 and the stop film 38 on the Z1 direction side. On the surface of the sacrificial layer 74 on the Z1 direction side, the insulating layers 33 and the sacrificial layers 75 are alternately stacked. On the surface of the uppermost sacrificial layer 75 on the Z1 direction side, the insulating layer 34 and the sacrificial layer 76 are provided in this order. On the surface of the sacrificial layer 76 on the Z1 direction side, the insulating layer 35 is provided.

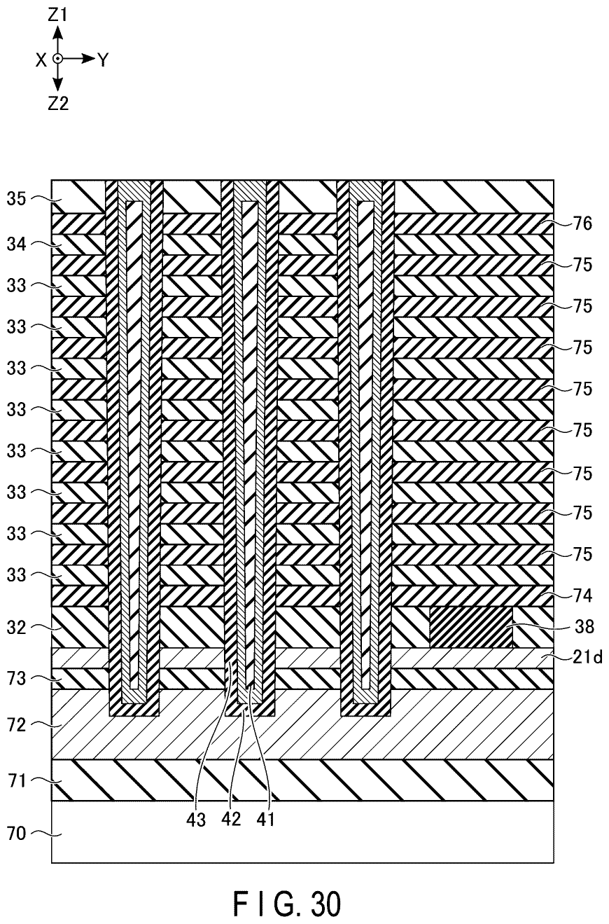

Next, as illustrated in FIG. 30, a plurality of holes (not illustrated) is provided in a region where memory pillars MP are to be provided in the stacked structure. Bottom surfaces of the holes reach the semiconductor layer 72. Thereafter, the stacked film 43, the semiconductor film 42, and the core film 41 are formed in this order in each hole, and each hole is filled. As a result, a structure corresponding to the memory pillar MP is formed. In the structure corresponding to the memory pillar MP, the stacked film 43 covers the end portion of the semiconductor film 42 on the Z2 direction side.

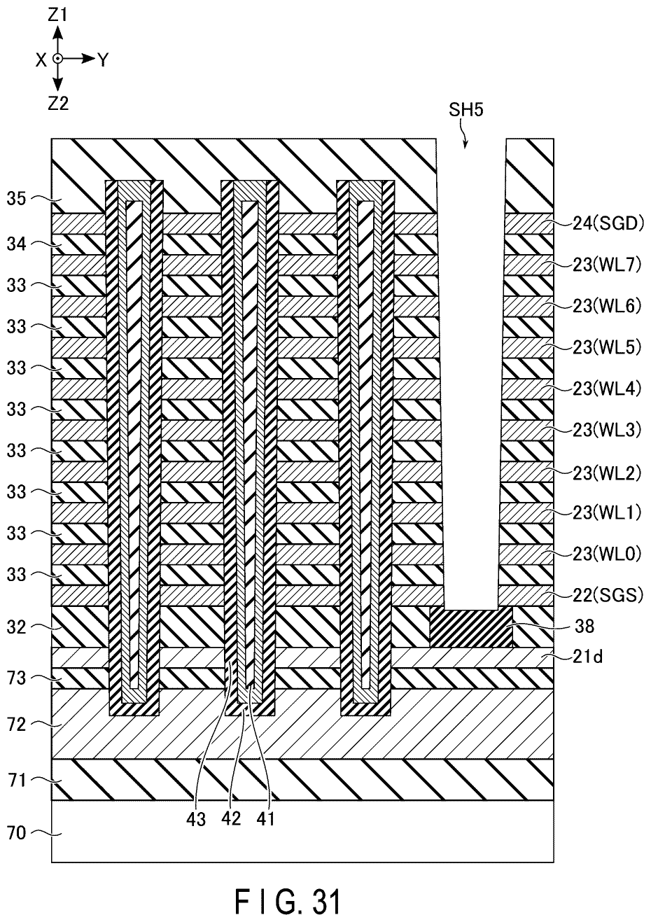

Next, as illustrated in FIG. 31, a groove SH5 is formed in a region where a member SLT is to be provided. A bottom surface of the groove SH5 reaches, for example, the stop film 38. Then, a replacement process of the stacked structure is executed via the groove SH5. As a result, the wiring layers 22, 23, and 24 are formed.

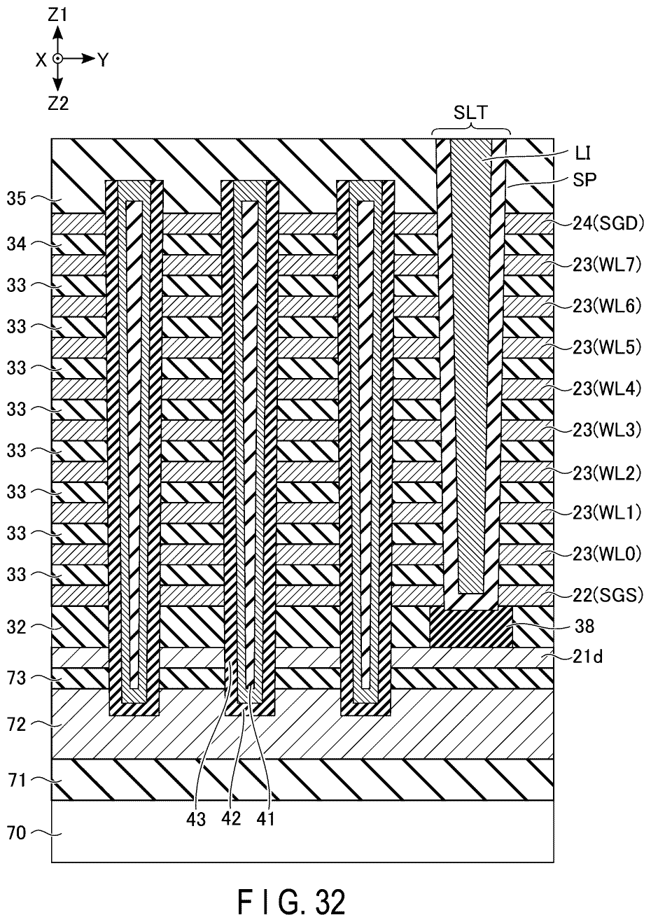

Next, as illustrated in FIG. 32, an insulating material SP and a filling material LI are formed in this order in the groove SH5, and the groove SH5 is filled. As a result, the member SLT is formed.

Thereafter, a structure on the Z1 direction side from the member SHE and the stacked wiring structure is formed, and the manufacturing of the memory chip 100 is completed. The subsequent steps are the same as those in the second embodiment.

### 3.3 Effects According to Third Embodiment

According to the third embodiment, the stop film 38 has a portion provided at the same position as the insulating layer 32 in the Z direction. The stop film 38 includes at least one substance selected from aluminum oxide (Al₂O₃), silicon carbide (SiC), and carbon (C). The stop film 38 extends in the XY plane so as to include at least a portion of the insulating material SP on the Z2 direction side with respect to the filling material LI (a bottom portion of the groove corresponding to the member SLT) as viewed in the Z direction. Thus, in a case where the member SLT is formed, etching on the stacked structure can be stopped by the stop film 38. Therefore, it is possible to prevent the filling material LI from being exposed in a case where the semiconductor film 42 of the memory pillar MP is exposed. Therefore, in a case where the semiconductor layer 21c is heated by the laser annealing treatment, it is possible to suppress that heat is deprived by the filling material LI having a relatively high thermal conductivity, and the semiconductor layer 21c in the vicinity of the member SLT is not sufficiently crystallized. In addition, crystallization of the semiconductor layer 21d in the vicinity of the member SLT can be promoted.

### 3.4 Modification of Third Embodiment

Various modifications can be applied to the above-described third embodiment.

### 3.4.1 First Modification of Third Embodiment

In the third embodiment described above, the case where the film thickness of the stop film 38 is substantially equal to that of the insulating layer 32 has been described, but the present invention is not limited thereto. The film thickness of the stop film 38 may be thinner than that of the insulating layer 32.

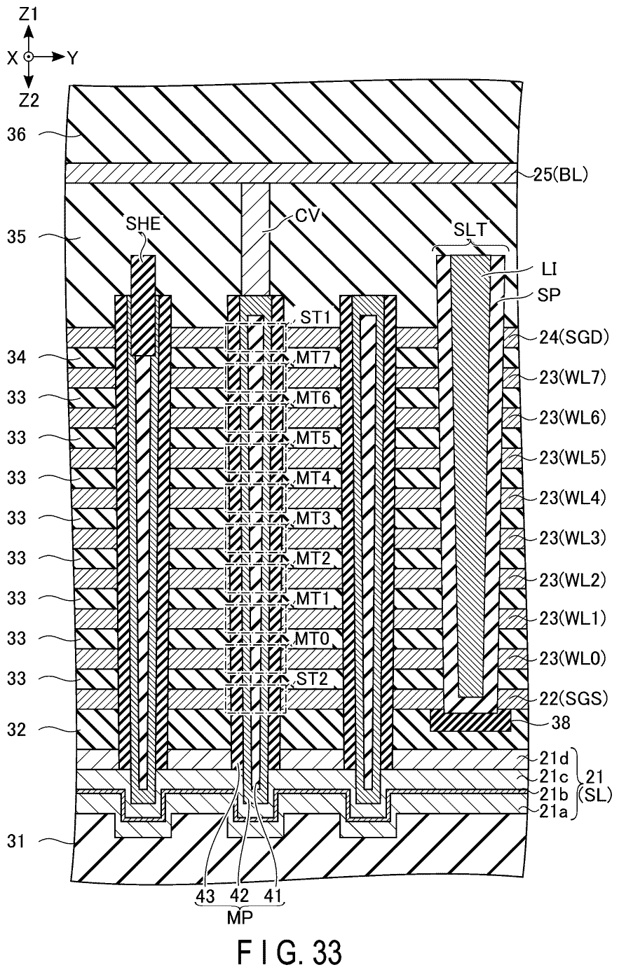

FIG. 33 is a cross-sectional view illustrating an example of a cross-sectional structure of a memory cell array included in a memory device according to a first modification of the third embodiment. FIG. 33 corresponds to FIG. 27 in the third embodiment.

As illustrated in FIG. 33, an insulating layer 32 is provided on a surface of a semiconductor layer 21d on the Z1 direction side. The insulating layer 32 has a shape recessed in the Z2 direction in a region including a portion overlapping a member SLT as viewed in the Z direction.

A stop film 38 is provided in a region (region recessed in the Z2 direction) including a portion overlapping the member SLT as viewed in the Z direction on the surface on the Z1 direction side of an insulating layer 32. The surface of the insulating layer 32 on the Z1 direction side and the surface of the stop film 38 on the Z1 direction side are aligned. In other words, the stop film 38 has a film thickness thinner than that of the insulating layer 32. Such a structure can be obtained by removing a part of the insulating layer 32 by anisotropic etching in a case where a groove SH4 is formed.

A wiring layer 22 is provided on the surfaces of the insulating layer 32 and the stop film 38 on the Z1 direction side. The structure on the Z1 direction side with respect to the wiring layer 22 is the same as that of the third embodiment.

In the above configuration, the end on the Z2 direction side of an insulating material SP is located in the stop film 38. As a result, an insulator including the insulating layer 32, the insulating material SP, and the stop film 38 can be interposed between the filling material LI and the wiring layer 21. Therefore, similarly to the third embodiment, it is possible to reduce the amount of heat transferred to the filling material LI in the heat generated by the laser annealing treatment. Therefore, crystallization of the semiconductor layers 21c and 21d in the vicinity of the member SLT can be promoted.

### 3.4.2 Second Modification of Third Embodiment

In addition, the film thickness of the stop film 38 may be thicker than that of the insulating layer 32.

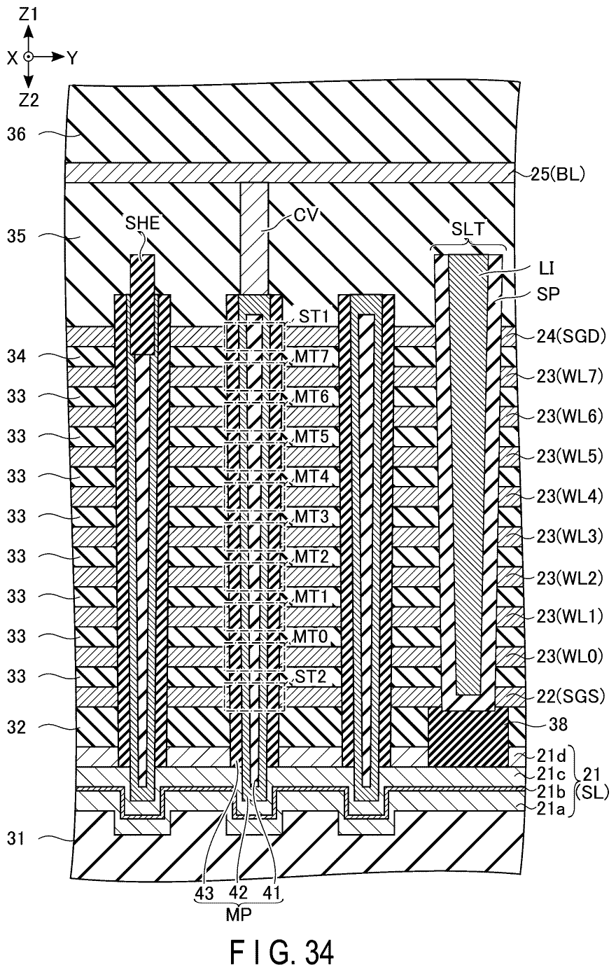

FIG. 34 is a cross-sectional view illustrating an example of a cross-sectional structure of a memory cell array included in a memory device according to a second modification of the third embodiment. FIG. 34 corresponds to FIG. 27 in the third embodiment.

As illustrated in FIG. 34, the stop film 38 is provided in a region including a portion overlapping the member SLT as viewed in the Z direction on the surface of the semiconductor layer 21c on the Z1 direction side.

In a region where the stop film 38 is not provided on the surface of the semiconductor layer 21c on the Z1 direction side, the semiconductor layer 21d and the insulating layer 32 are stacked in this order. The surface of the insulating layer 32 on the Z1 direction side and the surface of the stop film 38 on the Z1 direction side are aligned. In other words, the film thickness of the stop film 38 is larger than the film thickness of the insulating layer 32, and is substantially equal to the total film thickness of the semiconductor layer 21d and the insulating layer 32. Such a structure can be obtained by removing the insulating layer 32 and the semiconductor layer 21d by anisotropic etching in a case where a groove SH4 is formed.

A wiring layer 22 is provided on the surfaces of the insulating layer 32 and the stop film 38 on the Z1 direction side. The structure on the Z1 direction side with respect to the wiring layer 22 is the same as that of the third embodiment.

In the above configuration, the end on the Z2 direction side of an insulating material SP is located in the stop film 38. As a result, an insulator including an insulating material SP and the stop film 38 can be interposed between a filling material LI and a wiring layer 21. Therefore, similarly to the third embodiment, it is possible to reduce the amount of heat transferred to the filling material LI in the heat generated by the laser annealing treatment. Therefore, crystallization of the semiconductor layers 21c and 21d in the vicinity of the member SLT can be promoted.

### 3.4.3 Third Modification of Third Embodiment

In addition, the stop film 38 may reach the inside of the semiconductor layer 21c.

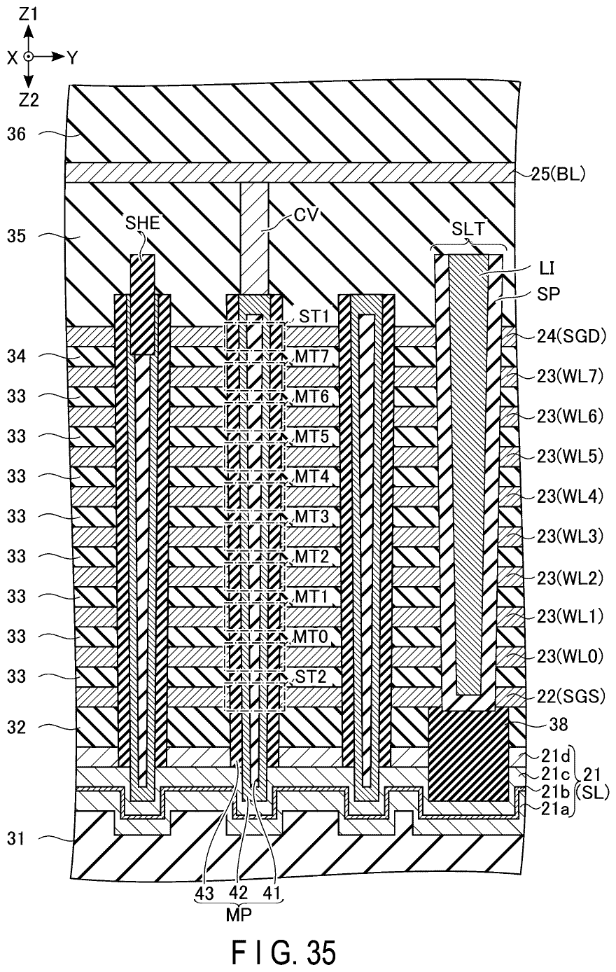

FIG. 35 is a cross-sectional view illustrating an example of a cross-sectional structure of a memory cell array included in a memory device according to a third modification of the third embodiment. FIG. 35 corresponds to FIG. 27 in the third embodiment.

As illustrated in FIG. 35, each of conductive layers 21a and 21b and semiconductor layer 21c has a shape in which potions overlapping memory pillars MP and a member SLT as viewed in the Z direction are Z2 direction side with respect to other potion.

A stop film 38 is provided in a region recessed in the Z2 direction corresponding to the member SLT on the surface of the semiconductor layer 21c on the Z1 direction side. In a region where the stop film 38 is not provided on the surface of the semiconductor layer 21c on the Z1 direction side, the semiconductor layer 21d and the insulating layer 32 are stacked in this order. The surface of the insulating layer 32 on the Z1 direction side and the surface of the stop film 38 on the Z1 direction side are aligned. Such a structure can be obtained by removing the insulating layer 32, the semiconductor layer 21d, and the insulating layer 73 by anisotropic etching in a case where a groove SH4 is formed, and further removing a part of the semiconductor layer 72.

In the above configuration, the end on the Z2 direction side of an insulating material SP is located in the stop film 38. As a result, an insulator including an insulating material SP and the stop film 38 can be interposed between a filling material LI and a wiring layer 21. Therefore, similarly to the third embodiment, it is possible to reduce the amount of heat transferred to the filling material LI in the heat generated by the laser annealing treatment. Therefore, crystallization of the semiconductor layers 21c and 21d in the vicinity of the member SLT can be promoted.

### 3.4.4 Fourth Modification of Third Embodiment

In addition, the stop film 38 may have a film thickness thinner than that of the insulating layer 32 and may be provided so as to be covered with the insulating layer 32.

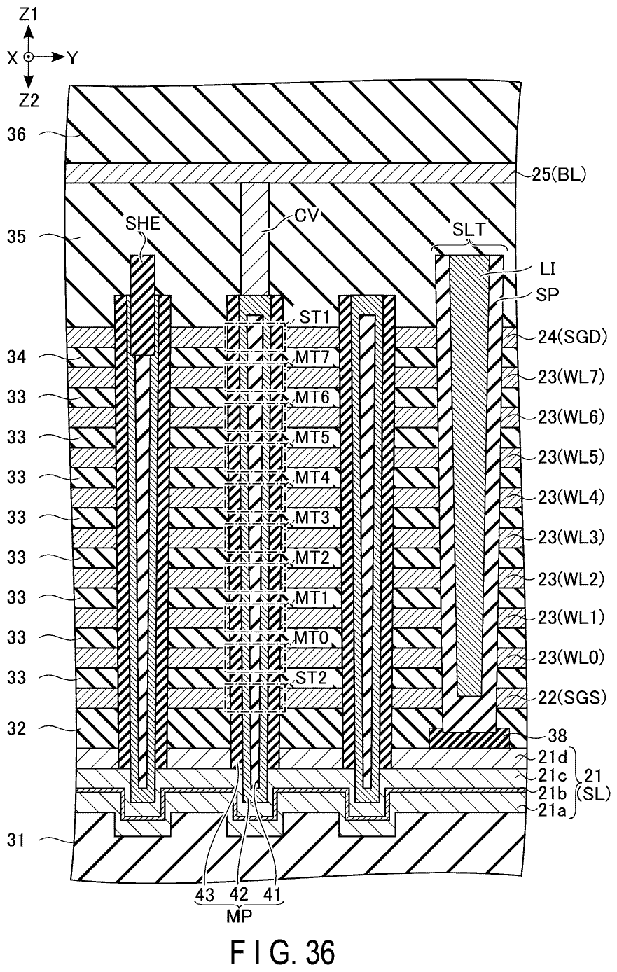

FIG. 36 is a cross-sectional view illustrating an example of a cross-sectional structure of a memory cell array included in a memory device according to a fourth modification of the third embodiment. FIG. 36 corresponds to FIG. 27 in the third embodiment.

As illustrated in FIG. 36, a stop film 38 is provided in a region including a portion overlapping a member SLT as viewed in the Z direction on a surface of a semiconductor layer 21d on the Z1 direction side. Then, an insulating layer 32 is provided so as to cover the stop film 38 and a region on the surface of the semiconductor layer 21d on the Z1 direction side where the stop film 38 is not provided. Such a structure can be obtained by further forming the insulating layer 32 on the surface on the Z1 direction side of the structure after the stop film 38 is embedded in the groove SH4.

On the surface of the insulating layer 32 on the Z1 direction side, the wiring layer 22 is provided. The structure on the Z1 direction side with respect to the wiring layer 22 is the same as that of the third embodiment.

In the above configuration, the end on the Z2 direction side of an insulating material SP is located in the stop film 38. As a result, an insulator including an insulating material SP and the stop film 38 can be interposed between a filling material LI and a wiring layer 21. Therefore, similarly to the third embodiment, it is possible to reduce the amount of heat transferred to the filling material LI in the heat generated by the laser annealing treatment. Therefore, crystallization of the semiconductor layers 21c and 21d in the vicinity of the member SLT can be promoted.

### 4. Fourth Embodiment

Next, a memory device according to a fourth embodiment will be described. The fourth embodiment is different from the third embodiment in that the stop film is provided on the Z2 direction side with respect to the insulating layer 32. In the following description, a configuration and a manufacturing method different from those of the third embodiment will be mainly described. Description of the same configuration and manufacturing method as those of the third embodiment will be omitted as appropriate.

### 4.1 Configuration

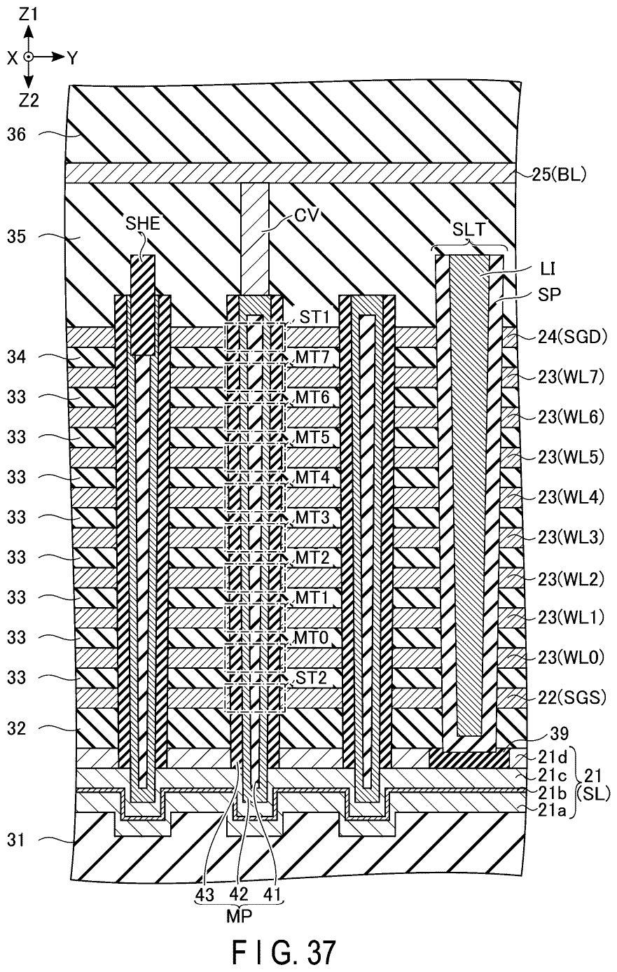

FIG. 37 is a cross-sectional view illustrating an example of a cross-sectional structure of a memory cell array included in a memory device according to a fourth embodiment. FIG. 37 corresponds to FIG. 27 in the third embodiment.

As illustrated in FIG. 37, in the fourth embodiment, a memory cell array 10 includes a stop film 39 instead of the stop film 38.

As in the third embodiment, the end portion of a member SLT on the Z2 direction side does not reach a wiring layer 21. Therefore, in each of conductive layers 21a and 21b and a semiconductor layer 21c, a region including a portion overlapping the member SLT as viewed in the Z direction has a flat shape.

A stop film 39 is provided in a region including a portion overlapping the member SLT as viewed in the Z direction on the surface of the semiconductor layer 21c on the Z1 direction side. The stop film 39 has a function of preventing the progress of etching in a case of forming a groove corresponding to the member SLT. The stop film 39 is, for example, an insulator containing at least one substance selected from aluminum oxide (Al₂O₃), silicon carbide (SiC), and carbon (C). The stop film 39 has a film type different from that of an insulating layer 32.

A semiconductor layer 21d is provided in a region where the stop film 39 is not provided on a surface of a semiconductor layer 21c on the Z1 direction side. The surface of the semiconductor layer 21d on the Z1 direction side and the surface of the stop film 39 on the Z1 direction side are aligned.

The insulating layer 32 is provided on the surface on the Z1 direction side of each of the semiconductor layer 21d and the stop film 39. The structure on the Z1 direction side with respect to the insulating layer 32 is the same as that of the third embodiment.

The filling material LI intersects the wiring layers 23 and 24 and the insulating layers 33 to 35. The filling material LI may or may not intersect the wiring layer 22.

An insulating material SP covers the side surface and the end surface on the Z2 direction side of the filling material LI. The end on the Z2 direction side of the insulating material SP is located in the stop film 39.

### 4.2 Manufacturing Method

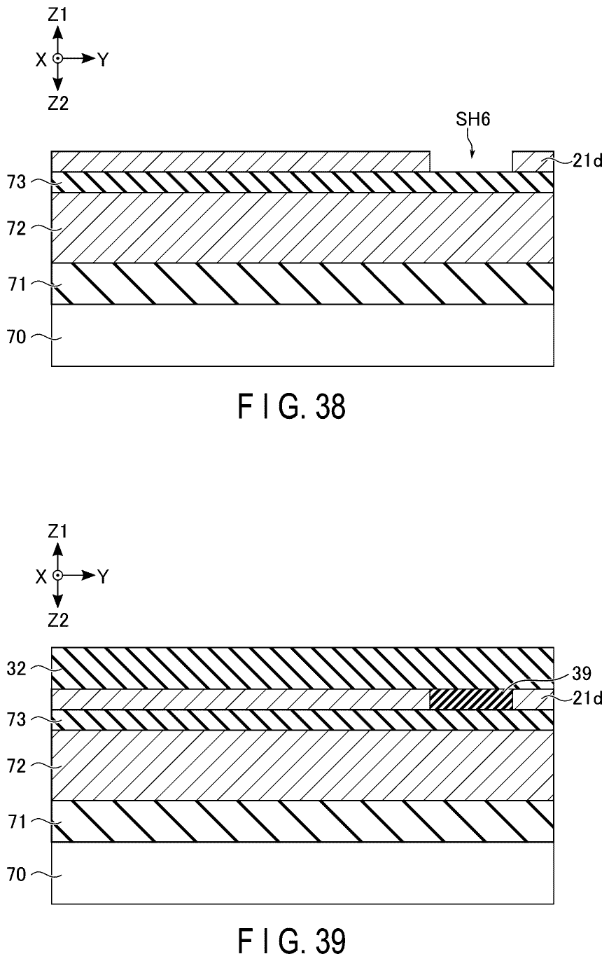

FIGS. 38 and 39 are diagrams illustrating an example of a structure in a process of manufacturing the memory device according to the fourth embodiment. FIGS. 38 and 39 are cross-sectional views in the process of manufacturing the memory cell array 10 in the memory chip 100, and correspond to FIG. 37.

First, as illustrated in FIG. 38, the insulating layer 71, the semiconductor layer 72, the insulating layer 73, and the semiconductor layer 21d are provided in this order on the surface of the substrate 70 on the Z1 direction side.

Then, a region of the semiconductor layer 21d where the stop film 39 is to be provided is removed by, for example, anisotropic etching. Thus, a groove SH6 is formed. The insulating layer 73 is exposed on the bottom surface of the groove SH6.

Next, as illustrated in FIG. 39, the groove SH6 is filled by the stop film 39. A portion of the stop film 39 provided outside the groove SH6 is etched back. As a result, the film thicknesses of the semiconductor layer 21d and the stop film 39 are equalized.

Then, a stacked structure corresponding to the stacked wiring structure is provided on the Z1 direction side with respect to the semiconductor layer 21d and the stop film 39. Specifically, the insulating layer 32 and the sacrificial layer 74 are laminated in this order on the surfaces of the semiconductor layer 21d and the stop film 39 on the Z1 direction side. On the surface of the sacrificial layer 74 on the Z1 direction side, the insulating layers 33 and the sacrificial layers 75 are alternately stacked. On the surface of the uppermost sacrificial layer 75 on the Z1 direction side, the insulating layer 34 and the sacrificial layer 76 are provided in this order. On the surface of the sacrificial layer 76 on the Z1 direction side, the insulating layer 35 is provided.

The subsequent steps are the same as those in the third embodiment.

### 4.3 Effects According to Fourth Embodiment

According to the fourth embodiment, the surface of the stop film 39 on the wiring layer 22 side is aligned with the surface of the insulating layer 32 on the semiconductor layer 21d side. The stop film 39 includes at least one substance selected from aluminum oxide (Al₂O₃), silicon carbide (SiC), and carbon (C). The stop film 39 extends in the XY plane so as to include at least a portion of the insulating material SP on the Z2 direction side with respect to the filling material LI (a bottom portion of the groove corresponding to the member SLT) as viewed in the Z direction. Thus, in a case where the member SLT is formed, etching on the stacked structure can be stopped by the stop film 39. Therefore, it is possible to prevent the filling material LI from being exposed in a case where the semiconductor film 42 of the memory pillar MP is exposed. Therefore, in a case where the semiconductor layer 21c is heated by the laser annealing treatment, it is possible to suppress that heat is deprived by the filling material LI having a relatively high thermal conductivity, and the semiconductor layer 21c in the vicinity of the member SLT is not sufficiently crystallized. In addition, crystallization of the semiconductor layer 21d in the vicinity of the member SLT can be promoted.

### 4.4 Modification of Fourth Embodiment

Various modifications can be applied to the above-described fourth embodiment.

For example, the stop film 39 may reach the inside of the semiconductor layer 21c.

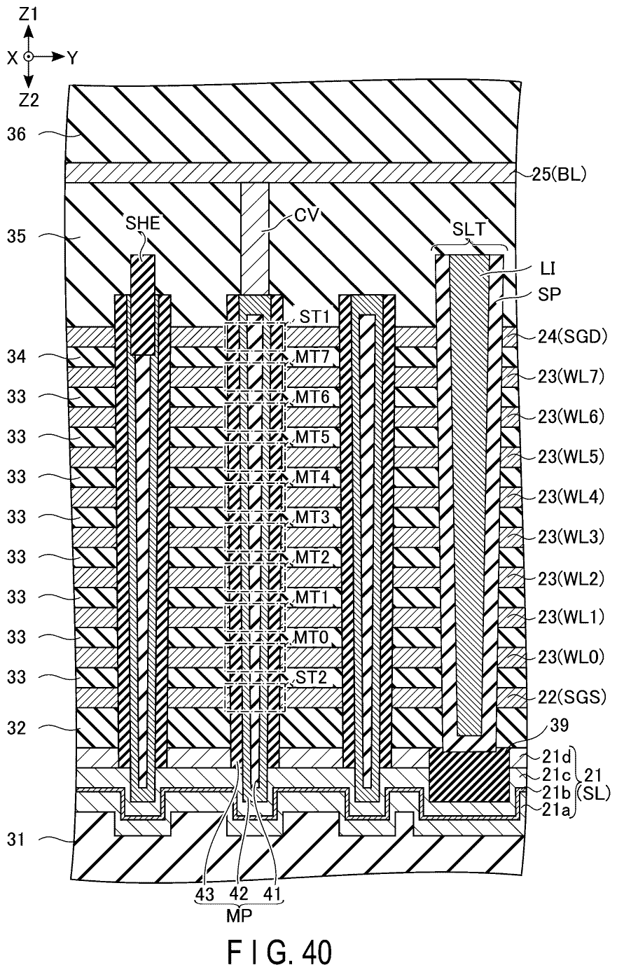

FIG. 40 is a cross-sectional view illustrating an example of a cross-sectional structure of a memory cell array included in a memory device according to a modification of the fourth embodiment. FIG. 40 corresponds to FIG. 37 in the fourth embodiment.

As illustrated in FIG. 40, each of conductive layers 21a and 21b and semiconductor layer 21c has a shape in which portions overlapping the memory pillars MP and the member SLT as viewed in the Z direction are Z2 direction side with respect to other portion.

A stop film 39 is provided in a region recessed in the Z2 direction corresponding to the member SLT on the surface of the semiconductor layer 21c on the Z1 direction side. A semiconductor layer 21d is provided in a region where the stop film 39 is not provided on a surface of a semiconductor layer 21c on the Z1 direction side. The surface of the semiconductor layer 21d on the Z1 direction side and the surface of the stop film 39 on the Z1 direction side are aligned. Such a structure can be obtained by removing the semiconductor layer 21d and the insulating layer 73 by anisotropic etching at the time of forming the groove SH6 and further removing a part of the semiconductor layer 72.

In the above configuration, the end on the Z2 direction side of the insulating material SP is located in the stop film 39. As a result, an insulator including an insulating material SP and the stop film 39 can be interposed between a filling material LI and a wiring layer 21. Therefore, similarly to the fourth embodiment, it is possible to reduce the amount of heat transferred to the filling material LI in the heat generated by the laser annealing treatment. Therefore, crystallization of the semiconductor layers 21c and 21d in the vicinity of the member SLT can be promoted.

While certain embodiments have been described, these embodiments have been presented by way of example only, and are not intended to limit the scope of the inventions. Indeed, the novel methods and devices described herein may be embodied in a variety of other forms; furthermore, various omissions, substitutions and changes in the form of the methods and devices described herein may be made without departing from the spirit of the inventions. The accompanying claims and their equivalents are intended to cover such forms or modifications as would fall within the scope and spirit of the inventions.

What is claimed is:

1. A memory device comprising:
a semiconductor layer;
a first wiring layer arranged apart from the semiconductor layer in a first direction without interposing another wiring layer;
a plurality of second wiring layers located on a side opposite to a side of the semiconductor layer with respect to the first wiring layer and arranged apart from each other in the first direction;
a plurality of memory pillars each extending in the first direction, being in contact with the semiconductor layer, and including portions respectively intersecting with the second wiring layers each functioning as a memory cell; and
a member extending in a first plane including the first direction and a second direction intersecting with the first direction and dividing the first wiring layer and the second wiring layers in a third direction intersecting with each of the first direction and the second direction, wherein
the member includes
a filling material extending in the first plane and having both ends in the first direction that are located on a side of the second wiring layers with respect to a semiconductor layer side surface of the first wiring layer, and
an insulating material provided between the filling material and each of the semiconductor layer, the first wiring layer, and the second wiring layers, and having a thermal conductivity that is lower than a thermal conductivity of the filling material.

2. The memory device according to claim 1, wherein
a length of the member in the third direction is longer than twice a length of a portion of the insulating material between the filling material and each of the second wiring layers.

3. The memory device according to claim 1, wherein
a length, in the first direction, of a portion of the insulating material on a side closer to the semiconductor layer than the filling material is longer than a length of a portion of the insulating material between the filling material and each of the second wiring layers.

4. The memory device according to claim 1, wherein
the filling material has a Young's modulus higher than a Young's modulus of the insulating material.

5. The memory device according to claim 1, wherein
a portion of the insulating material on a side closer to the semiconductor layer than the filling material includes
a first insulating film that is continuous with a portion of the insulating material between the filling material and each of the second wiring layers, and
a second insulating film provided between the first insulating film and the semiconductor layer.

6. The memory device according to claim 1, wherein
a surface of the semiconductor layer on an opposite side to a side of the first wiring layer has unevenness in a region overlapping the memory pillars in the first direction.

7. A memory device comprising:
a semiconductor layer;
a first wiring layer arranged apart from the semiconductor layer in a first direction without interposing another wiring layer;
a plurality of second wiring layers located on a side opposite to a side of the semiconductor layer with respect to the first wiring layer and arranged apart from each other in the first direction;
a plurality of memory pillars each extending in the first direction, being in contact with the semiconductor layer, and including portions respectively intersecting with the second wiring layers each functioning as a memory cell;
a member extending in a first plane including the first direction and a second direction intersecting with the first direction and dividing the first wiring layer and the second wiring layers in a third direction intersecting with each of the first direction and the second direction, the member including a filling material and an insulating material, the insulating material being provided between the filling material and each of the semiconductor layer, the first wiring layer, and the second wiring layers and having a thermal conductivity that is lower than a thermal conductivity of the filling material; and
an insulating film provided between the insulating material and the semiconductor layer, and including a portion of the insulating material as viewed in the first direction, the portion being located on a side closer to the semiconductor layer than the filling material.

8. The memory device according to claim 7, wherein
the insulating film includes at least one substance selected from aluminum oxide (Al₂O₃), silicon carbide (SiC), and carbon (C).

9. The memory device according to claim 7, wherein
the insulating film extends in a second plane including the second direction and the third direction.

10. The memory device according to claim 9, further comprising
a first insulating layer provided between the insulating film and the first wiring layer and having a film type different from a film type of the insulating film.

11. The memory device according to claim 9, further comprising
a second insulating layer provided between the insulating film and the semiconductor layer and having a film type different from a film type of the insulating film.

12. The memory device according to claim 9, wherein
the insulating film is in contact with each of the semiconductor layer and the first wiring layer.

13. The memory device according to claim 7, further comprising
a third insulating layer including a portion that is provided at a substantially same position as the insulating film in the first direction and having a film type different from a film type of the insulating film.

14. The memory device according to claim 13, wherein
the insulating film has a film thickness substantially equal to a film thickness of the third insulating layer.

15. The memory device according to claim 13, wherein
the insulating film has a film thickness thinner than a film thickness of the third insulating layer, and
the third insulating layer further includes a portion between the insulating film and the semiconductor layer.

16. The memory device according to claim 13, wherein
the insulating film has a film thickness thicker than a film thickness of the third insulating layer.

17. The memory device according to claim 13, wherein
the insulating film has a film thickness thinner than a film thickness of the third insulating layer and is in contact with the semiconductor layer.

18. The memory device according to claim 7, further comprising
a fourth insulating layer provided between the semiconductor layer and the first wiring layer and having a film type different from a film type of the insulating film, wherein
a surface of the insulating film on a side of the first wiring layer is aligned with a surface of the fourth insulating layer on a side of the semiconductor layer.

19. The memory device according to claim 7, wherein
the filling material has a Young's modulus higher than a Young's modulus of the insulating material.

20. The memory device according to claim 7, wherein
a surface of the semiconductor layer on an opposite side to a side of the first wiring layer has unevenness in a region overlapping the memory pillars in the first direction.
